(19) United States
(12) Patent Application Publication
(10) Pub. No.: US 2026/0163336 A1
(43) Pub. Date: Jun. 11, 2026

(54) SURFACE EMITTING LASER

(71) Applicant: SONY GROUP CORPORATION, Tokyo (JP)

(72) Inventors: Tomohiro MAKINO, Kanagawa (JP); Tatsushi HAMAGUCHI, Kanagawa (JP); Jared Alexander KEARNS, Kanagawa (JP); Kentaro HAYASHI, Kanagawa (JP); Maiko ITO, Kanagawa (JP)

(21) Appl. No.: 18/854,594

(22) PCT Filed: Mar. 6, 2023
(86) PCT No.: PCT/JP2023/008331

§ 371 Date: Aug. 4, 2025

(30) Foreign Application Priority Data
Apr. 14, 2022 (JP) 2022-067213

(51) Int. Cl. H01S 5/34; H01S 5/183

(52) U.S. Cl. CPC H01S 5/3406; H01S 5/183

(57) ABSTRACT

Provided is a surface emitting laser capable of suppressing complication of a structure and capable of controlling a polarization direction.

The surface emitting laser according to the present technology includes a resonator including a first structure and a second structure stacked on each other and an active layer disposed between the first and second structures, and the first structure and/or the second structure is provided with a stress application structure that applies a stress that distorts the active layer in an in-plane direction to the active layer. According to the surface emitting laser of the present technology, it is possible to provide the surface emitting laser capable of suppressing complication of a structure and capable of controlling a polarization direction.

### TECHNICAL FIELD

The technology according to the present disclosure (hereinafter also referred to as “the present technology”) relates to a surface emitting laser.

### BACKGROUND ART

Conventionally, in a vertical cavity surface emitting laser (VCSEL), there has been proposed a surface emitting laser in which a concave mirror is introduced into a reflecting mirror for disabling diffraction loss due to lateral optical field confinement. However, since the surface emitting laser has a symmetric structure in a plane, a polarization direction of emitted light is not determined, and light in various directions is emitted depending on a sample. Furthermore, in the surface emitting laser, a phenomenon in which the polarization direction changes during driving has also been confirmed.

To control the polarization direction, a surface emitting laser in which a grating is provided in a resonator and anisotropy is imparted to reflectance has been proposed (see, for example, Patent Documents 1 and 2).

### CITATION LIST

### Patent Document

Patent Document 1: Japanese Patent Application Laid-Open No. 2014-29979
Patent Document 2: Japanese Patent Application Laid-Open No. 2009-117578

### SUMMARY OF THE INVENTION

### Problems to be Solved by the Invention

However, in the surface emitting laser, there is room for improvement in suppressing complication of a structure.

Therefore, a main object of the present technology is to provide a surface emitting laser capable of suppressing complication of a structure and capable of controlling a polarization direction.

### Solutions to Problems

The present technology provides a surface emitting laser including:
a resonator including
a first structure and a second structure stacked on each other and
an active layer disposed between the first and second structures, in which
the first structure and/or the second structure is provided with a stress application structure that applies a stress that distorts the active layer in an in-plane direction to the active layer.

The stress application structure may have shape anisotropy in the in-plane direction.

The stress application structure may distort the active layer in at least one direction in a plane.

The stress application structure may have shape anisotropy in directions orthogonal to each other in the in-plane direction.

The resonator may be provided with a current confinement region that sets a light emitting region of the active layer, and the stress application structure may include a first configuration portion provided on one side of a center of the light emitting region in plan view and a second configuration portion provided on another side.

The first and second configuration portions may be substantially point-symmetric with respect to the center of the light emitting region in plan view.

The stress application structure may be provided in at least a part of the first structure and/or the second structure in a stacking direction.

The stress application structure may have a single layer structure or a multilayer structure.

A plurality of the stress application structures may be disposed at different positions in at least a stacking direction.

The plurality of stress application structures may include first and second stress application structures on a same side in the stacking direction of the active layer, the first and second stress application structures each may have an applied stress having a same positive or negative sign, and an angle formed by stress application directions of the first and second stress application structures in plan view may be less than 45°.

The plurality of stress application structures may include first and second stress application structures on a same side in the stacking direction of the active layer, the first and second stress application structures each may have an applied stress having a different positive or negative sign, and an angle formed by stress application directions of the first and second stress application structures in plan view may exceed 45°.

The plurality of stress application structures may include first and second stress application structures on different sides in the stacking direction of the active layer, the first and second stress application structures each may have an applied stress having a same positive or negative sign, and an angle formed by stress application directions of the first and second stress application Structures in plan view may exceed 45°.

The plurality of stress application structures may include first and second stress application structures on different sides in the stacking direction of the active layer, the first and second stress application structures each may have an applied stress having a different positive or negative sign, and an angle formed by stress application directions of the first and second stress application structures in plan view may be less than 45°.

The first structure may include a first reflecting mirror, the second structure may include a second reflecting mirror, and the first reflecting mirror and/or the second reflecting mirror may have the stress application structure.

The second structure may include a reflecting mirror, and at least one intermediate layer disposed between the reflecting mirror and the active layer, and the intermediate layer may have the stress application structure.

The second structure may include a transparent conductive film disposed between the reflecting mirror and the active layer, and the intermediate layer may be disposed between the reflecting mirror and the transparent conductive film.

The first structure may include a reflecting mirror, and at least one intermediate layer disposed between the reflecting mirror and the active layer, and the intermediate layer may have the stress application structure.

The intermediate layer may be a substrate.

The second structure may be provided with an electrode, and the electrode may have the stress application structure.

The first structure may be provided with an electrode, and the electrode may have the stress application structure.

### BRIEF DESCRIPTION OF DRAWINGS

FIG. 1A is a cross-sectional view (part 1) of a surface emitting laser according to Example 1 of an embodiment of the present technology. FIG. 1B is a cross-sectional view (part 2) of the surface emitting laser according to Example 1 of the embodiment of the present technology.

FIGS. 2A to 2C are views illustrating planar configuration examples 1 to 3 of a second reflecting mirror of the surface emitting laser in FIG. 1.

FIGS. 3A to 3C are views illustrating planar configuration examples 4 to 6 of the second reflecting mirror of the surface emitting laser in FIG. 1.

FIG. 4 is a flowchart for describing an example of a method of manufacturing the surface emitting laser in FIG. 1.

FIGS. 5A and 5B are cross-sectional views for each process of an example of a method of manufacturing the surface emitting laser in FIG. 1.

FIGS. 6A and 6B are cross-sectional views for each process of the example of the method of manufacturing the surface emitting laser in FIG. 1.

FIGS. 7A and 7B are cross-sectional views for each process of the example of the method of manufacturing the surface emitting laser in FIG. 1.

FIGS. 8A and 8B are cross-sectional views for each process of the example of the method of manufacturing the surface emitting laser in FIG. 1.

FIG. 9 is a cross-sectional view for each process of the method of manufacturing the surface emitting laser illustrated in FIG. 1.

FIG. 10A is a cross-sectional view (part 1) of a surface emitting laser according to Example 2 of the embodiment of the present technology. FIG. 10B is a cross-sectional view (part 2) of the surface emitting laser according to Example 2 of the embodiment of the present technology.

FIGS. 11A to 11C are views illustrating planar configuration examples 1 to 3 of a second reflecting mirror of the surface emitting laser in FIG. 10.

FIGS. 12A to 12C are views illustrating planar configuration examples 4 to 6 of the second reflecting mirror of the surface emitting laser in FIG. 10.

FIG. 13A is a cross-sectional view (part 1) of a surface emitting laser according to Example 3 of the embodiment of the present technology. FIG. 13B is a cross-sectional view (part 2) of the surface emitting laser according to Example 3 of the embodiment of the present technology.

FIGS. 14A to 14C are views illustrating planar configuration examples 1 to 3 of a second reflecting mirror of the surface emitting laser in FIG. 13.

FIGS. 15A to 15C are views illustrating planar configuration examples 4 to 6 of the second reflecting mirror of the surface emitting laser in FIG. 13.

FIG. 16A is a cross-sectional view (part 1) of a surface emitting laser according to Example 4 of the embodiment of the present technology. FIG. 16B is a cross-sectional view (part 2) of the surface emitting laser according to Example 4 of the embodiment of the present technology.

FIGS. 17A to 17C are views illustrating planar configuration examples 1 to 3 of a second reflecting mirror of the surface emitting laser in FIG. 16.

FIGS. 18A to 18C are views illustrating planar configuration examples 4 to 6 of the second reflecting mirror of the surface emitting laser in FIG. 16.

FIG. 19A is a cross-sectional view (part 1) of a surface emitting laser according to Example 5 of the embodiment of the present technology. FIG. 19B is a cross-sectional view (part 2) of the surface emitting laser according to Example 5 of the embodiment of the present technology.

FIG. 20 is a view illustrating a planar configuration example of a second reflecting mirror of the surface emitting laser in FIG. 19.

FIG. 21A is a cross-sectional view (part 1) of a surface emitting laser according to Example 6 of the embodiment of the present technology. FIG. 21B is a cross-sectional view (part 2) of the surface emitting laser according to Example 6 of the embodiment of the present technology.

FIG. 22 is a view illustrating a planar configuration example of a second reflecting mirror of the surface emitting laser in FIG. 21.

FIG. 23A is a cross-sectional view (part 1) of a surface emitting laser according to Example 7 of the embodiment of the present technology. FIG. 23B is a cross-sectional view (part 2) of the surface emitting laser according to Example 7 of the embodiment of the present technology.

FIGS. 24A and 24B are views illustrating planar configuration examples 1 and 2 of a second reflecting mirror of the surface emitting laser in FIG. 23.

FIG. 25A is a cross-sectional view (part 1) of a surface emitting laser according to Example 8 of the embodiment of the present technology. FIG. 25B is a cross-sectional view (part 2) of the surface emitting laser according to Example 8 of the embodiment of the present technology.

FIG. 26 is a view illustrating a planar configuration example of a first reflecting mirror of the surface emitting laser in FIG. 25.

FIG. 27A is a cross-sectional view (part 1) of a surface emitting laser according to Example 9 of the embodiment of the present technology. FIG. 27B is a cross-sectional view (part 2) of the surface emitting laser according to Example 9 of the embodiment of the present technology.

FIG. 28 is a view illustrating a planar configuration example of a first reflecting mirror of the surface emitting laser in FIG. 27.

FIG. 29A is a cross-sectional view (part 1) of a surface emitting laser according to Example 10 of the embodiment of the present technology. FIG. 29B is a cross-sectional view (part 2) of the surface emitting laser according to Example 10 of the embodiment of the present technology.

FIG. 30A is a view illustrating a planar configuration example of a second reflecting mirror of the surface emitting laser in FIG. 29. FIG. 30B is a view illustrating a planar configuration example of a first reflecting mirror of the surface emitting laser in FIG. 29.

FIG. 31A is a cross-sectional view (part 1) of a surface emitting laser according to Example 11 of the embodiment of the present technology. FIG. 31B is a cross-sectional view (part 2) of the surface emitting laser according to Example 11 of the embodiment of the present technology.

FIG. 32A is a view illustrating a planar configuration example of a second reflecting mirror of the surface emitting laser in FIG. 31. FIG. 32B is a view illustrating a planar configuration example of a first reflecting mirror of the surface emitting laser in FIG. 31.

FIG. 33A is a cross-sectional view (part 1) of a surface emitting laser according to Example 12 of the embodiment of the present technology. FIG. 33B is a cross-sectional view (part 2) of the surface emitting laser according to Example 12 of the embodiment of the present technology.

FIG. 34 is a view illustrating a planar configuration example of a first reflecting mirror of the surface emitting laser in FIG. 33.

FIG. 35A is a cross-sectional view (part 1) of a surface emitting laser according to Example 13 of the embodiment of the present technology. FIG. 35B is a cross-sectional view (part 2) of the surface emitting laser according to Example 13 of the embodiment of the present technology.

FIG. 36 is a view illustrating a planar configuration example of an anode electrode and a cathode electrode of the surface emitting laser in FIG. 35.

FIG. 37A is a cross-sectional view (part 1) of a surface emitting laser according to Example 14 of the embodiment of the present technology. FIG. 35B is a cross-sectional view (part 2) of the surface emitting laser according to Example 14 of the embodiment of the present technology.

FIG. 38 is a view illustrating a planar configuration example of an anode electrode and a cathode electrode of the surface emitting laser in FIG. 37.

FIG. 39A is a cross-sectional view (part 1) of a surface emitting laser according to Example 15 of the embodiment of the present technology. FIG. 39B is a cross-sectional view (part 2) of the surface emitting laser according to Example 15 of the embodiment of the present technology.

FIG. 40 is a view illustrating a planar configuration example of an anode electrode and a cathode electrode of the surface emitting laser in FIG. 39.

FIGS. 41A to 41D are views for describing a method of controlling a polarization direction by a stress application structure that causes a tensile strain in an active layer.

FIGS. 42A to 42D are views for describing a method of controlling a polarization direction by a stress application structure that causes a compressive strain in an active layer.

FIGS. 43A to 43F are views for describing a method of controlling magnitude of an applied stress by a stress application structure that causes a tensile strain in an active layer.

FIGS. 44A to 44F are views for describing a method of controlling magnitude of an applied stress by a stress application structure that causes a compressive strain in an active layer.

FIG. 45 is a view illustrating a planar configuration example 1 of a surface emitting laser according to Example 16 of the embodiment of the present technology.

FIG. 46 is a view illustrating a planar configuration example 2 of the surface emitting laser according to Example 16 of the embodiment of the present technology.

FIG. 47A is a cross-sectional view (part 1) of a surface emitting laser according to Example 17 of the embodiment of the present technology. FIG. 47B is a cross-sectional view (part 2) of the surface emitting laser according to Example 17 of the embodiment of the present technology.

FIG. 48A is a view illustrating a planar configuration example of a stress application structure of a surface emitting laser array according to Example 18 of the embodiment of the present technology. FIG. 48B is a view illustrating a planar configuration example of a stress application structure of a surface emitting laser array according to Example 19 of the embodiment of the present technology.

FIG. 49A is a view illustrating a planar configuration example of a stress application structure of a surface emitting laser according to Example 20 of the embodiment of the present technology. FIG. 49B is a view illustrating a planar configuration example of a stress application structure of a surface emitting laser according to Example 21 of the embodiment of the present technology.

FIG. 50A is a view illustrating an example in which a plane mirror is used as a first reflecting mirror of a surface emitting laser. FIG. 50B is a view illustrating an example in which a concave mirror is used as a first reflecting mirror of a surface emitting laser.

FIGS. 51A to 51E are views illustrating Variation 1 of a stress application structure.

FIGS. 52A to 52E are views illustrating Variation 2 of the stress application structure.

FIGS. 53A to 53C are views illustrating Variation 3 of the stress application structure.

FIG. 54 is a diagram illustrating an application example of the surface emitting laser according to the present technology to a distance measuring device.

FIG. 55 is a block diagram illustrating an example of a schematic configuration of a vehicle control system.

FIG. 56 is an explanatory diagram illustrating an example of installation positions of distance measuring devices.

### MODE FOR CARRYING OUT THE INVENTION

Hereinafter, preferred embodiments of the present technology will be described in detail with reference to the accompanying drawings. Note that, in the present specification and the drawings, components having substantially the same functional configurations are denoted by the same reference signs, and redundant descriptions are omitted. The embodiments to be described below illustrate representative embodiments of the present technology, and the scope of the present technology is not narrowly interpreted by these embodiments. In the present specification, even in a case where it is described that a surface emitting laser according to the present technology exhibits a plurality of effects, it suffices that the surface emitting laser according to the present technology exhibits at least one effect. The effects described in the present specification are merely examples and are not limited, and other effects may be exerted.

Furthermore, the description will be given in the following order.
0. Introduction
1. Surface Emitting Laser According to Example 1 of Embodiment of Present Technology
2. Surface Emitting Laser According to Example 2 of Embodiment of Present Technology
3. Surface Emitting Laser According to Example 3 of Embodiment of Present Technology
4. Surface Emitting Laser According to Example 4 of Embodiment of Present Technology
5. Surface Emitting Laser According to Example 5 of Embodiment of Present Technology
6. Surface Emitting Laser According to Example 6 of Embodiment of Present Technology
7. Surface Emitting Laser According to Example 7 of Embodiment of Present Technology
8. Surface Emitting Laser According to Example 8 of Embodiment of Present Technology
9. Surface Emitting Laser According to Example 9 of Embodiment of Present Technology
10. Surface Emitting Laser According to Example 10 of Embodiment of Present Technology
11. Surface Emitting Laser According to Example 11 of Embodiment of Present Technology
12. Surface Emitting Laser According to Example 12 of embodiment of present technology
13. Surface Emitting Laser According to Example 13 of Embodiment of Present Technology
14. Surface Emitting Laser According to Example 14 of Embodiment of Present Technology
15. Surface Emitting Laser According to Example 15 of Embodiment of Present Technology
16. Surface Emitting Laser According to Example 16 of Embodiment of Present Technology
17. Surface Emitting Laser According to Example 17 of Embodiment of Present Technology
18. Surface Emitting Laser Array According to Example 18 of Embodiment of Present Technology
19. Surface Emitting Laser Array According to Example 19 of Embodiment of Present Technology
20. Surface Emitting Laser According to Example 20 of Embodiment of Present Technology
21. Surface Emitting Laser According to Example 21 of Embodiment of Present Technology
22. Modification of Present Technology
23. Application Example to Electronic Device
24. Example in Which Surface Emitting Laser Is Applied to Distance Measuring Device
25. Example in Which Distance Measuring Device Is Mounted on Moving Body

### 0. Introduction

Conventionally, a vertical cavity surface emitting laser (VCSEL) does not have a fixed polarization direction unlike an end surface emitting semiconductor laser, and takes various directions depending on a sample. Furthermore, a phenomenon in which the polarization direction changes during driving has also been confirmed. Therefore, for example, a method of etching a DBR included in a resonator to form a grating and impart anisotropy to reflectance has been proposed. However, it is difficult to manufacture the grating itself, and a structure becomes finer as a wavelength is shorter. In particular, processing difficulty becomes significantly high in a blue wavelength band. That is, in the conventional VCSEL, there is room for improvement in suppressing complication of the structure.

Therefore, after intensive studies, the inventors have devised a surface emitting laser according to the present technology as a surface emitting laser capable of suppressing complication of a structure and capable of controlling a polarization direction.

Specifically, the inventors have succeeded in extracting linearly polarized light whose polarization direction depends on the direction of a strain by imparting the strain to an active layer of a VCSEL in at least one direction in a plane perpendicular to an emission direction. To supplement, an optical gain changes depending on the direction of the strain imparted to the active layer. As a result, when a sufficient strain is imparted, the polarization direction of emitted light can be controlled in one direction.

As a method of imparting a strain in at least one direction to the active layer, for example, a residual stress at the time of forming a layer other than the active layer of the VCSEL can be used. In a case where the layer has an asymmetric shape (anisotropic shape), a strain is applied to the active layer in at least one direction, and the polarization direction is controlled in one direction. Furthermore, in a case where the layer has a symmetric shape (isotropic shape), a stress is generally isotropically distributed in the plane, and thus the layer is processed into a shape having anisotropy so that a strain in at least one direction is imparted to the active layer. To supplement, in a case where the layer has a symmetric shape, the residual stress at the time of film formation is isotropically distributed in the plane. Therefore, to obtain high anisotropy in one direction, the layer is patterned so as to have an appropriate pattern calculated by structural analysis by simulation. This pattern is a stress application structure that applies a stress to the active layer. Therefore, polarization control can be performed without changing the shape of a light emitting region (current implantation region) of the active layer, and thus restriction on beam quality such as a near field pattern (NFP) of the emitted light is reduced. Moreover, there is no need for wavelength order microfabrication.

Furthermore, in the stress application structure, even for various chip structures of the VCSEL, an appropriate pattern shape can be derived by setting calculation conditions for structural analysis so as to conform to the chip structures.

Furthermore, the stress application structure can be combined with other polarization control methods such as using an elliptical lens-shaped portion or the like as a base of a reflecting mirror, and implementation of high polarization controllability can be expected.

The inventors have contrived the pattern shape and arrangement of the stress application structure in order to obtain high strain anisotropy (polarization controllability) in the active layer of the VCSEL, and have developed a surface emitting laser according to an embodiment of the present technology as a surface emitting laser into which the idea has been introduced.

Hereinafter, an embodiment of the surface emitting laser according to the present technology will be described in detail with some examples.

### 1. Surface Emitting Laser According to Example 1 of Embodiment of Present Technology

Hereinafter, a surface emitting laser according to Example 1 of an embodiment of the present technology will be described with reference to the drawings.

### Configuration of Surface Emitting Laser

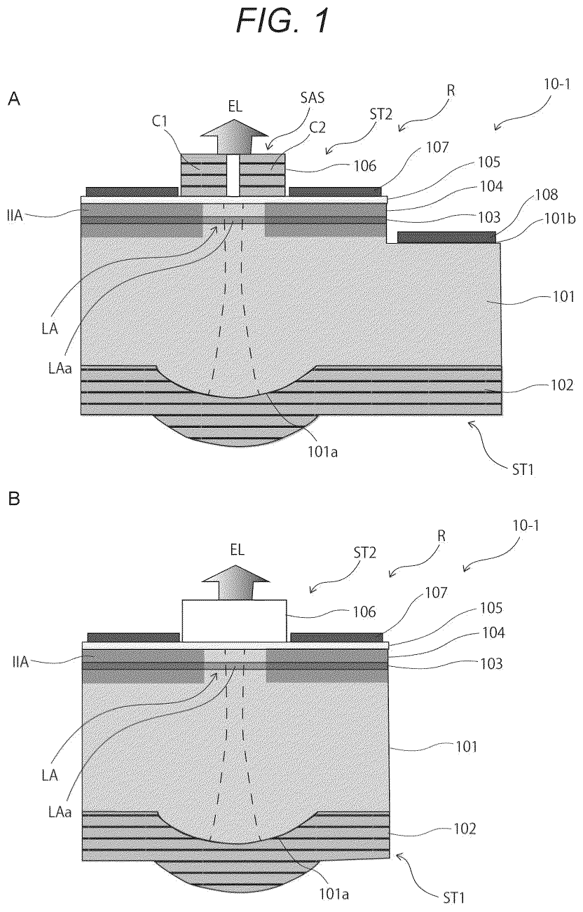

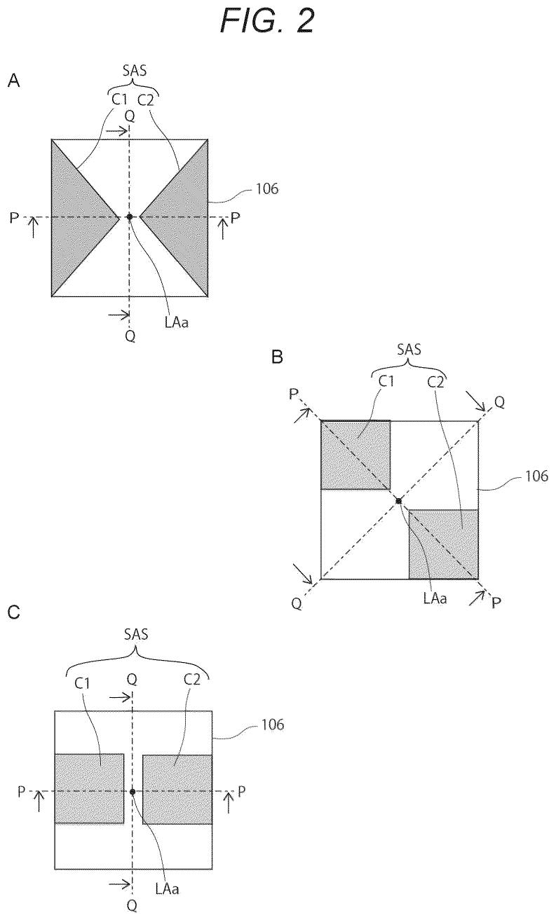

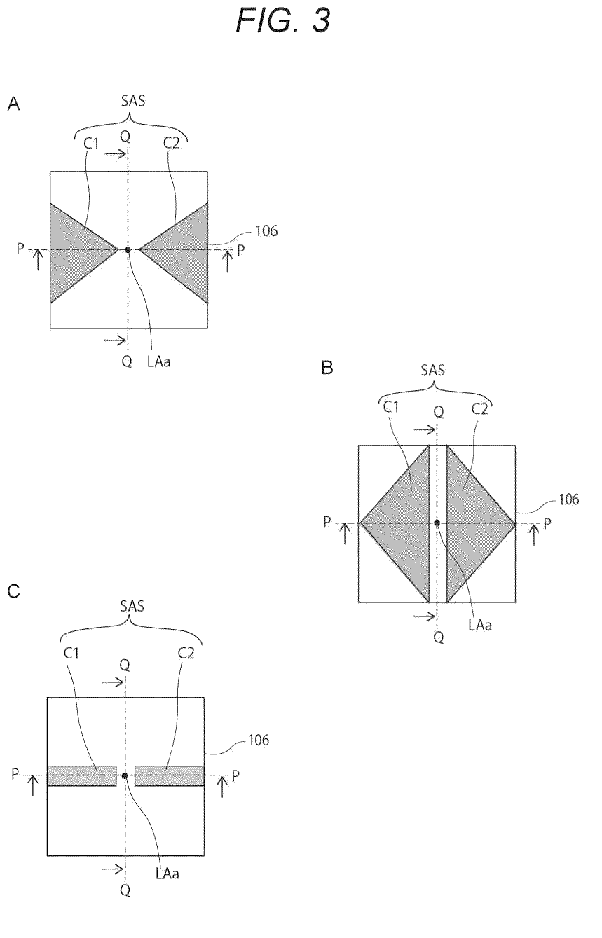

FIG. 1A is a cross-sectional view (part 1) of a surface emitting laser 10-1 according to Example 1 of an embodiment of the present technology. FIG. 1B is a cross-sectional view (part 2) of the surface emitting laser 10-1 according to Example 1 of the embodiment of the present technology. FIGS. 2A to 2C are views illustrating planar configuration examples 1 to 3 of a second reflecting mirror 106 of the surface emitting laser 10-1. FIGS. 3A to 3C are views illustrating planar configuration examples 4 to 6 of the second reflecting mirror 106 of the surface emitting laser 10-1. FIG. 1A is a cross-sectional view taken along line P-P in FIGS. 2A to 2C and FIGS. 3A to 3C. FIG. 1B is a cross-sectional view taken along line Q-Q in FIGS. 2A to 2C and FIGS. 3A to 3C. Hereinafter, for the sake of convenience, the upper side in the cross-sectional view of FIG. 1 and the like will be described as an upper side, and the lower side in the cross-sectional view of FIG. 1 and the like will be described as a lower side.

### Overall Configuration

As an example, as illustrated in FIGS. 1A and 1B, the surface emitting laser 10-1 includes a resonator R including first and second structures ST1 and ST2 stacked on each other and an active layer 103 disposed between the first and second structures ST1 and ST2. The first structure ST1 includes a first reflecting mirror 102. The second structure ST2 includes a second reflecting mirror 106. That is, the surface emitting laser 10-1 is a vertical cavity surface emitting laser (VCSEL) in which the active layer 103 is disposed between the first and second reflecting mirrors 102 and 106 stacked on each other. The surface emitting laser 10-1 is driven by, for example, a laser driver. A thickness of the surface emitting laser 10-1 is preferably 100 μm or less.

Oscillation wavelengths of the surface emitting laser 10-1 are, for example, 405 nm, 447 nm, 457 nm, 488 nm, 515 nm, and a red band.

As an example, the first reflecting mirror 102 includes a concave mirror, and the second reflecting mirror 106 is a plane mirror.

As an example, the first structure ST1 further includes a substrate 101 as an intermediate layer disposed between the first reflecting mirror 102 and the active layer 103.

As an example, the first structure ST1 further includes a cathode electrode 108 disposed on a cutaway electrode installation portion 101b provided on the substrate 101.

As an example, the second structure ST2 further includes a transparent conductive film 105 as an intermediate layer disposed between the active layer 103 and the second reflecting mirror 106.

As an example, the second structure ST2 further includes a cladding layer 104 as an intermediate layer disposed between the transparent conductive film 105 and the active layer 103.

As an example, a circling ion implantation region IIA (high resistance region) as a current confinement region for setting a light emitting region LA (current implantation region) of the active layer 103 is provided in the first structure ST1 and the second structure ST2. A region surrounded by the ion implantation region IIA of the active layer 103 is the light emitting region LA. As an example, the ion implantation region IIA exists in an upper portion of the substrate 101 (a portion where the electrode installation portion 101b is not provided) and a peripheral region of the active layer 103 and the cladding layer 104. Examples of ion species in the ion implantation region IIA include B⁺⁺ and H⁺⁺. Note that the current confinement region is not limited to the ion implantation region, and may be, for example, an insulating region including a dielectric or the like.

The light emitting region LA is located between the concave mirror of the first reflecting mirror 102 and the second reflecting mirror 106. A resonator length of the resonator R, which is a distance between the first and second reflecting mirrors 102 and 106, is, for example, 15 to 50 μm.

As an example, the second structure ST2 further includes an anode electrode 107 provided in a circumferential shape (for example, a ring shape) on a surface (upper surface) of the transparent conductive film 105 on a side opposite to the active layer 103 side so as to surround the second reflecting mirror 106. The anode electrode 107 surrounds the light emitting region LA in plan view.

The first structure ST1 and/or the second structure ST2 (for example, the second structure ST2) is provided with a stress application structure SAS for applying a stress for distorting the active layer 103 in an in-plane direction to the active layer 103.

### Substrate

The substrate 101 is an n-type cladding layer and includes, for example, an n-GaN substrate. The substrate 101 has a lens-shaped portion 101a serving as a base of the concave mirror of the first reflecting mirror 102 on a surface (lower surface) opposite to the active layer 103 side. The lens-shaped portion 101a is located at a position corresponding to the light emitting region LA. It is preferable that a center of the lens-shaped portion 101a and a center LAa of the light emitting region LA substantially coincide with each other in plan view. The lens-shaped portion 101a is convex to the side opposite to the active layer 103 side. A surface of the lens-shaped portion 101a is, for example, a curved surface such as a spherical surface or a paraboloid surface. A lens diameter of the lens-shaped portion 101a is, for example, 30 to 50 μm.

### First Reflecting Mirror

The first reflecting mirror 102 has a concave mirror having positive power, and thus can reduce a diffraction loss by confining a lateral optical field. The first reflecting mirror 102 includes, for example, a dielectric multilayer film reflecting mirror. The dielectric multilayer film reflecting mirror is constituted by, for example, Ta₂O₅/SiO₂, SiO₂/SiN, SiO₂/Nb₂O₅, or the like. In the dielectric multilayer film reflecting mirror, the thickness of each refractive index layer is, for example, 127 nm, and the number of pairs is 7.5 pairs or more. A radius of curvature of the concave mirror of the first reflecting mirror 102 is, for example, 10 to 400 μm. The concave mirror of first reflecting mirror 102 has a circular shape in plan view, for example. As an example, a reflectance of the first reflecting mirror 102 is set to be slightly higher than a reflectance of the second reflecting mirror 106. That is, the second reflecting mirror 106 is a reflecting mirror on an emission side. Note that the reflectance of the second reflecting mirror 106 may be slightly higher than the reflectance of the first reflecting mirror 102, and the first reflecting mirror 102 may be used as a reflecting mirror on the emission side.

### Active Layer

As an example, the active layer 103 has a five-layered multiple quantum well structure in which an In_{0.04}Ga_{0.96}N layer (barrier layer) and an In_{0.16}Ga_{0.84}N layer (well layer) are stacked.

### Cladding Layer

The cladding layer 104 is a p-type cladding layer and is constituted by, for example, a p-GaN layer.

### Transparent Conductive Film

The transparent conductive film 105 functions as a buffer layer that enhances hole injection efficiency into the active layer 103 and prevents leakage. The transparent conductive film 105 is constituted by, for example, ITO, ITiO, AZO, ZnO, SnO, SnO₂, SnO₃, TiO, TiO₂, graphene, or the like.

### Second Reflecting Mirror

The plane mirror as the second reflecting mirror 106 includes, for example, a dielectric multilayer film reflecting mirror. The dielectric multilayer film reflecting mirror includes, for example, Ta₂O₅/SiO₂, SiN/SiO₂, or the like. The dielectric multilayer film reflecting mirror as the second reflecting mirror 106 has an isotropic shape such as a square shape or a circular shape in plan view, for example. Note that the second reflecting mirror 106 is not limited to a plane mirror, and may be, for example, a concave mirror.

### Ion Implantation Region

The ion implantation region IIA is formed by implanting high concentration ions (for example, B⁺⁺ or the like). The ion implantation region IIA has a higher resistance (carrier conductivity is low) than a region surrounded by the ion implantation region IIA, and functions as a current confinement region. A current confinement diameter by the ion implantation region IIA is, for example, 3 to 10 μm.

### Anode Electrode

The anode electrode 107 is constituted by, for example, at least one metal (including an alloy) selected from the group including Au, Ag, Pd, Pt, Ni, Ti, V, W, Cr, Al, Cu, Zn, Sn, and In. In a case where the anode electrode 107 has a stacked structure, the anode electrode is constituted by a material such as Ti/Au, Ti/Al, Ti/Al/Au, Ti/Pt/Au, Ni/Au, Ni/Au/Pt, Ni/Pt, Pd/Pt, or Ag/Pd, for example. The anode electrode 107 is connected to an anode (positive electrode) of a laser driver.

### Cathode Electrode

The cathode electrode 108 is constituted by, for example, at least one metal (including an alloy) selected from the group constituted by Au, Ag, Pd, Pt, Ni, Ti, V, W, Cr, Al, Cu, Zn, Sn, and In. In a case where the cathode electrode 108 has a stacked structure, the cathode electrode is constituted by a material such as Ti/Au, Ti/Al, Ti/Al/Au, Ti/Pt/Au, Ni/Au, Ni/Au/Pt, Ni/Pt, Pd/Pt, or Ag/Pd, for example. The cathode electrode 108 is electrically connected to a cathode (negative electrode) of the laser driver.

### Stress Application Structure

The second reflecting mirror 106 of the second structure ST2 has the stress application structure SAS. That is, the second reflecting mirror 106 is the reflecting mirror and is also the stress application structure SAS.

As an example, the stress application structure SAS is provided in the entire region in a thickness direction (stacking direction or an up-down direction) of the second reflecting mirror 106. That is, the stress application structure SAS has a layer structure, more specifically, a multilayer structure including the dielectric multilayer film reflecting mirror as the second reflecting mirror 106.

The stress application structure SAS distorts the active layer 103 in at least one direction in the plane. Therefore, the polarization direction of the emitted light of the surface emitting laser 10-1 can be controlled in one direction. Here, “controlling the polarization direction in one direction” is synonymous with “the polarization direction becomes dominant in one direction”.

The stress application structure SAS has shape anisotropy in directions (for example, a P-P line direction and a Q-Q line direction in each of FIGS. 2A to 2C and FIGS. 3A to 3C) orthogonal to each other in the in-plane direction. Specifically, the stress application structure SAS includes a first configuration portion Cl provided on one side of the center LAa of the light emitting region LA in plan view and a second configuration portion C2 provided on another side. As an example, each of the first and second configuration portions C1 and C2 includes a dielectric multilayer film reflecting mirror, and a periphery thereof is a void. Since the void is formed in the second reflecting mirror 106 as described above, heat dissipation can be improved. The first and second configuration portions C1 and C2 may face each other with a part including the center LAa of the light emitting region LA interposed therebetween, or may face each other with the entire light emitting region LA interposed therebetween in plan view.

The first and second configuration portions C1 and C2 are substantially point-symmetric with respect to the center LAa of the light emitting region LA in plan view (see FIGS. 2A to 2C and FIGS. 3A to 3C). Examples of the shape in plan view of each of the first and second configuration portions C1 and C2 include a polygon such as a triangle or a quadrangle, a circle, and an ellipse.

As the first and second configuration portions C1 and C2 are closer to the center LAa of the light emitting region LA, and the first and second configuration portions C1 and C2 are larger, the stress applied to the active layer 103 becomes larger. Note that the distance between each of the first and second configuration portions C1 and C2 and the center LAa of the light emitting region LA in plan view is preferably set to an appropriate distance that can reduce an influence on laser characteristics. It is preferable to form the first and second configuration portions C1 and C2 such that a strain of, for example, about 1×10⁻⁵ to 9×10⁻³ is imparted to the active layer 103.

For example, in a case where a stress application direction (an arrangement direction of the first and second configuration portions C1 and C2, or the P-P line direction of FIGS. 2A to 2C and FIGS. 3A to 3C) by the stress application structure SAS is a tensile direction (a direction facing outward from the center LAa of the light emitting region LA), that is, in a case where a tensile strain in the P-P line direction occurs in the active layer 103, the polarization direction of the surface emitting laser 10-1 is controlled in a direction substantially perpendicular to the stress application direction (P-P line direction).

For example, in a case where the stress application direction (the arrangement direction of the first and second configuration portions C1 and C2, or the P-P line direction of FIGS. 2A to 2C and FIGS. 3A to 3C) by the stress application structure SAS is a compressive direction (a direction facing the center LAa of the light emitting region LA), that is, in a case where a compressive strain in the P-P line direction occurs in the active layer 103, the polarization direction of the surface emitting laser 10-1 is controlled in a direction substantially parallel to the stress application direction (P-P line direction).

### Operation of Surface Emitting Laser

Hereinafter, an operation of the surface emitting laser 10-1 will be described.

In the surface emitting laser 10-1, when a driving voltage is applied between the anode electrode 107 and the cathode electrode 108 by a laser driver, a current flowing from the anode side of the laser driver through the anode electrode 107 is injected into the active layer 103 through the transparent conductive film 105 while being narrowed in the ion implantation region IIA. At this time, the active layer 103 emits light, and the light reciprocates between the first and second reflecting mirrors 102 and 106 while being amplified by the active layer 103 (at this time, the light is reflected while being condensed in a vicinity of the active layer 103 by the concave mirror of the first reflecting mirror 102, and is reflected toward the active layer 103 as parallel light or weak diffused light by the plane mirror as the second reflecting mirror 106), and is emitted from the second reflecting mirror 106 as laser light when an oscillation condition is satisfied. At this time, the polarization direction of the laser light as the emitted light is controlled in one direction by a stress application action on the active layer 103 by the stress application structure SAS. The current injected into the active layer 103 flows out from the cathode electrode 108 to a cathode side of the laser driver via the substrate 101.

### Method of Manufacturing Surface Emitting Laser

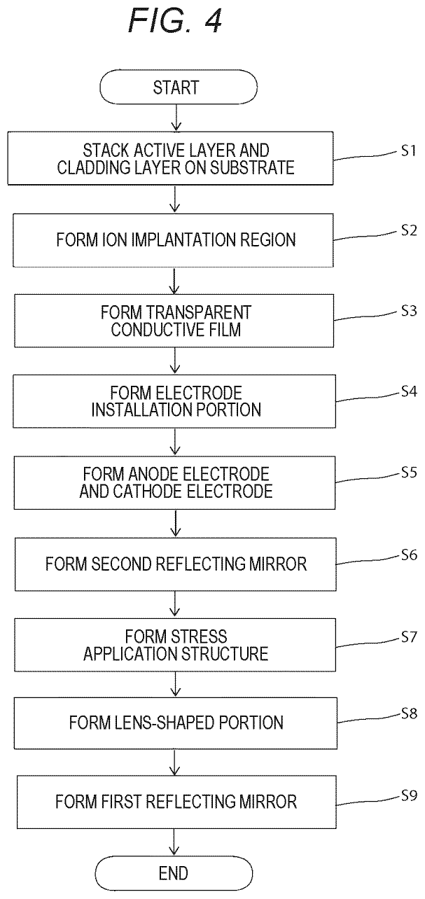

Hereinafter, a method of manufacturing the surface emitting laser 10-1 will be described with reference to the flowchart of FIG. 4 and the like. Here, as an example, a plurality of the surface emitting lasers 10-1 is simultaneously generated on one wafer (hereinafter referred to as a “substrate 101” for convenience) to serve as a base material of the substrate 101 (for example, an n-GaN substrate). Next, the plurality of surface emitting lasers 10-1 integrated in series is separated from each other to obtain chip-shaped surface emitting lasers 10-1 (surface emitting laser chips).

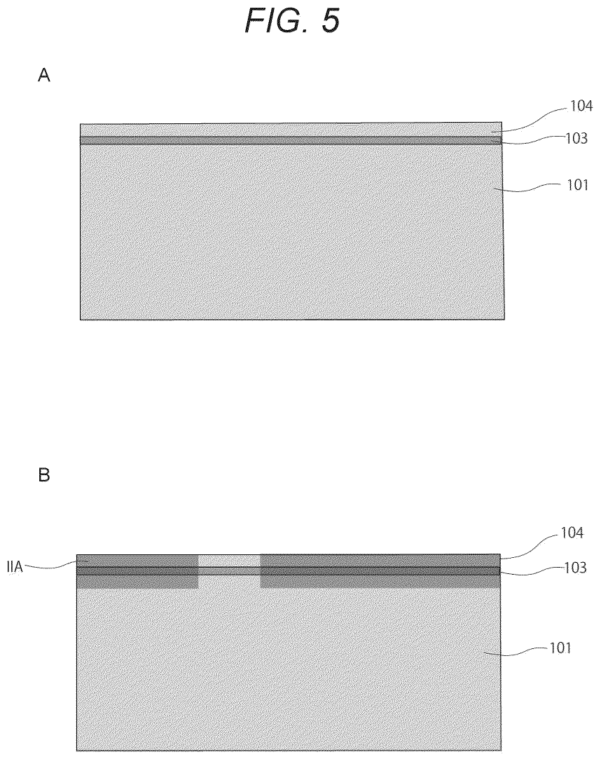

In step S1, the active layer 103 and the cladding layer 104 are stacked on the substrate 101 (see FIG. 5A). Specifically, the active layer 103 and the cladding layer 104 are grown in this order on the substrate 101 in a growth chamber by a metal organic chemical vapor deposition method (MOCVD method) or a molecular beam epitaxy method (MBE method) to form a stacked body.

In step S2, the ion implantation region IIA is formed (see FIG. 5B). Specifically, a protective film constituted by resist, SiO₂, or the like is formed to cover a portion other than the position where the ion implantation region IIA is formed on the stacked body, and ions (for example, B⁺⁺) are implanted into the stacked body from the cladding layer 104 side using the protective film as a mask. At this time, it is assumed that an implantation depth of the ion implantation reaches an inside of the substrate 101.

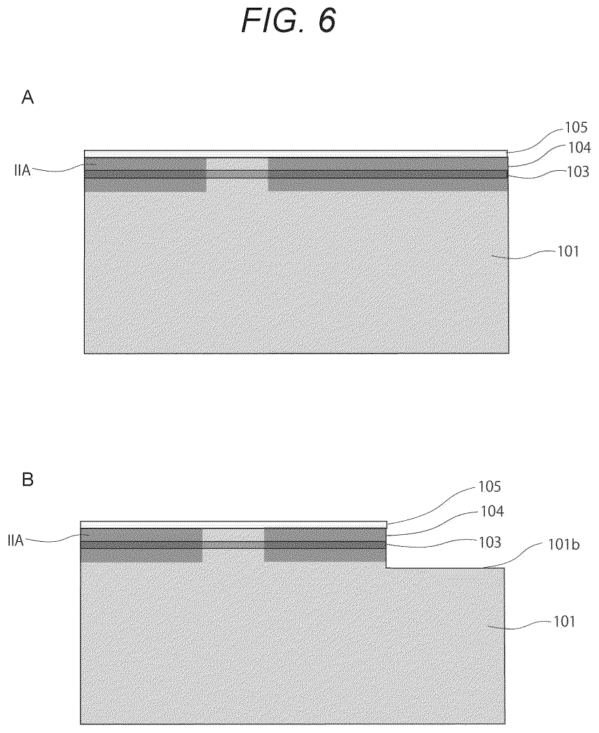

In step S3, the transparent conductive film 105 is formed (see FIG. 6A). Specifically, the transparent conductive film 105 is formed on the cladding layer 104 by, for example, a vacuum vapor deposition method, sputtering, or the like.

In step S4, the electrode installation portion 101b is formed (see FIG. 6B). Specifically, a resist pattern that covers a position other than the position where the electrode installation portion 101b is formed on the stacked body is formed, and the stacked body is etched using the resist pattern as a mask. At this time, etching is performed until an etching bottom surface is positioned in the substrate 101. As a result, the cutaway electrode installation portion 101b is formed in the stacked body.

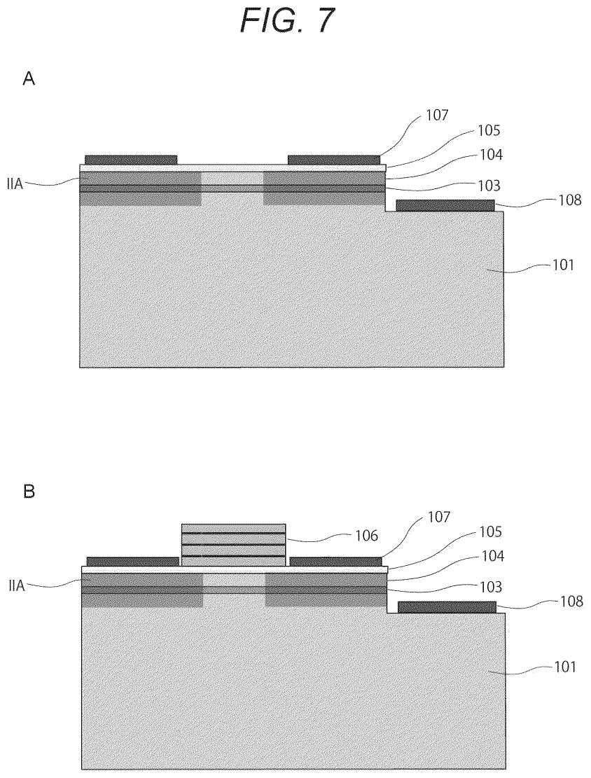

In step S5, the anode electrode 107 and the cathode electrode 108 are formed (see FIG. 7A). Specifically, for example, a lift-off method is used to form the anode electrode 107 on the transparent conductive film 105, and form the cathode electrode 108 on the electrode installation portion 101b.

In step S6, the second reflecting mirror 106 (for example, a plane mirror) is formed (see FIG. 7B). Specifically, first, a dielectric multilayer film to be the second reflecting mirror 106 is formed on the entire surface by, for example, a vacuum vapor deposition method, a sputtering method, a CVD method, or the like. Next, a resist pattern that covers only the dielectric multilayer film to be the second reflecting mirror 106 is formed, and etching is performed using the resist pattern as a mask to leave only the dielectric multilayer film to be the second reflecting mirror 106.

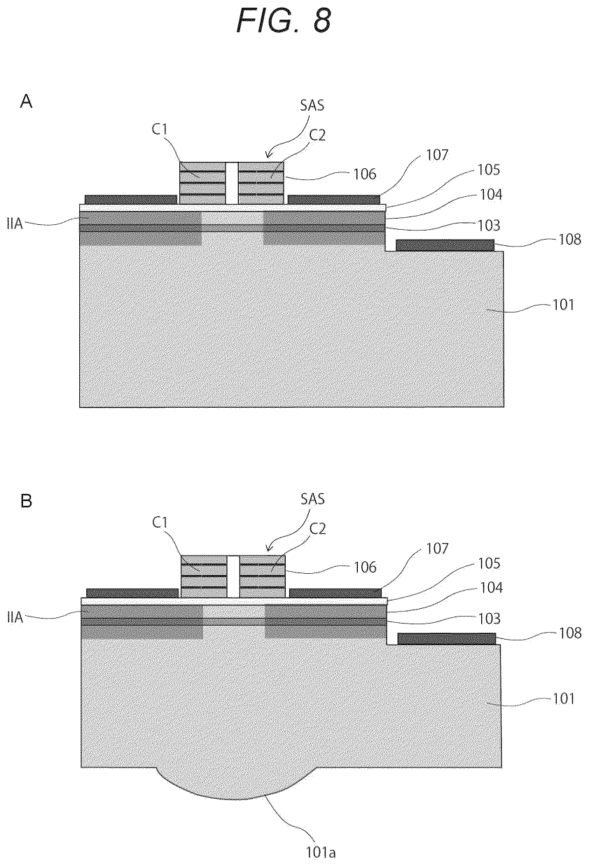

In step S7, the stress application structure SAS is formed (see FIG. 8A). Specifically, a resist pattern for forming the first and second configuration portions C1 and C2 of the stress application structure SAS on the second reflecting mirror 106 is formed on the second reflecting mirror 106. Next, the first and second configuration portions C1 and C2 of the stress application structure SAS are formed by etching the second reflecting mirror 106 using the resist pattern as a mask. At this time, a residual stress at the time of film formation of the second reflecting mirror 106 is controlled in at least one direction by the stress application structure SAS, and is applied to the active layer 103. Therefore, the active layer 103 is distorted in at least one direction, and the polarization direction can be controlled in one direction.

In step S8, the lens-shaped portion 101a is formed (see FIG. 8B). Specifically, first, a resist is formed at the position where the lens-shaped portion 101a is formed on a back surface of the substrate 101 by photolithography. Next, for example, the resist is formed into a lens shape (for example, a substantially hemispherical shape) by reflow at a temperature of 200° C. Next, etching is performed using the resist as a mask to form the lens-shaped portion 101a in, for example, a substantially hemispherical shape.

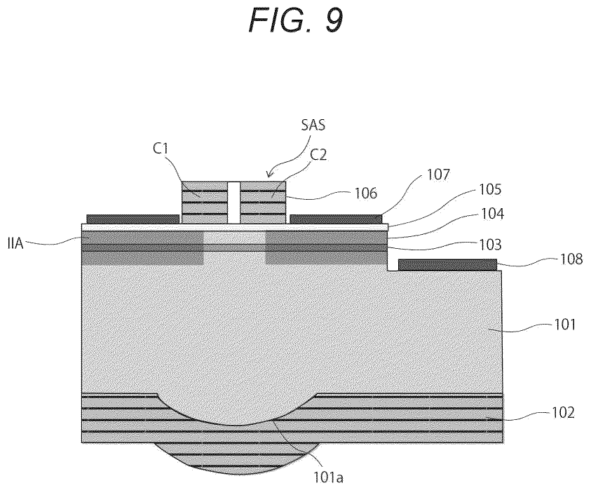

In step S9, the first reflecting mirror 102 is formed (see FIG. 9). Specifically, the material of the first reflecting mirror 102 (for example, a dielectric multilayer film) is formed on the back surface of the substrate 101 on which the lens-shaped portion 101a has been formed by, for example, a vacuum vapor deposition method, a sputtering method, a CVD method, or the like. Therefore, the first reflecting mirror 102 including the concave mirror having a shape following the lens-shaped portion 101a is formed. As a result, a plurality of the surface emitting lasers 10-1 is generated on the substrate 101. Thereafter, the plurality of surface emitting lasers 10-1 integrated in series is separated by dicing to obtain the chip-shaped surface emitting lasers 10-1 (surface emitting laser chips). Thereafter, the surface emitting laser 10-1 is mounted on, for example, a CAN package. More specifically, the surface of the surface emitting laser 10-1 on the first reflecting mirror 102 side is soldered to a CAN package.

### Effects of Surface Emitting Laser

Hereinafter, effects of the surface emitting laser 10-1 according to Example 1 of the embodiment of the present technology will be described.

The surface emitting laser 10-1 according to Example 1 of the embodiment of the present technology includes the resonator R including the first structure ST1 including the first reflecting mirror 102, the second structure ST2 including the second reflecting mirror 106, and the active layer 103 disposed between the first and second structures ST1 and ST2, and the first structure ST1 and/or the second structure ST2 is provided with the stress application structure SAS for applying a stress that distorts the active layer 103 in the in-plane direction to the active layer 103.

Therefore, the active layer 103 is distorted in the in-plane direction, and thus the polarization direction is controlled depending on the direction of the strain. That is, according to the surface emitting laser 10-1, it is possible to control the polarization direction without providing a complicated structure such as a grating, for example.

As a result, according to the surface emitting laser 10-1, it is possible to provide the surface emitting laser capable of suppressing complication of the structure and capable of controlling the polarization direction.

The stress application structure SAS has shape anisotropy in the in-plane direction. Thus, it is possible to control the polarization direction in a certain direction.

The stress application structure SAS distorts the active layer 103 in at least one direction in the plane. Thus, it is possible to control the polarization direction in one direction.

The stress application structure SAS has shape anisotropy in directions orthogonal to each other in the in-plane direction. Therefore, it is possible to control the polarization direction in one direction with the simple structure.

The first structure ST1 and/or the second structure ST2 is provided with the ion implantation IIA as a current confinement region for setting the light emitting region LA of the active layer 103, and the stress application structure SAS has the first and second configuration portions C1 and C2 facing each other with the center LAa of the light emitting region LA interposed therebetween in plan view. Thus, it is possible to efficiently control the polarization direction in one direction.

The first and second configuration portions C1 and C2 are substantially point-symmetric with respect to the center LAa of the light emitting region LA in plan view. Therefore, the stress application structure SAS can accurately control the stress to be applied to the active layer 103 in one direction, and can eventually accurately control the polarization direction in one direction.

The second reflecting mirror 106 that is a part of the second structure ST2 in the thickness direction has the stress application structure SAS. Therefore, it is possible to use the residual stress at the time of film formation of the second reflecting mirror 106 as the stress applied to the active layer 103 by the stress application structure SAS.

The stress application structure SAS has a layer structure (for example, a multilayer structure) . Therefore, it is possible to form the stress application Structure SAS by film formation and etching.

The first reflecting mirror 102 includes a concave mirror. Therefore, it is possible to suppress a diffraction loss.

The resonator length of the resonator R is 50 μm or less. Therefore, it is possible to set the radius of curvature and the diameter of the concave mirror of the first reflecting mirror 102 to suitable values (for example, the radius of curvature is 400 μm or less, and the diameter is 50 μm or less).

### 2. Surface Emitting Laser According to Example 2 of Embodiment of Present Technology

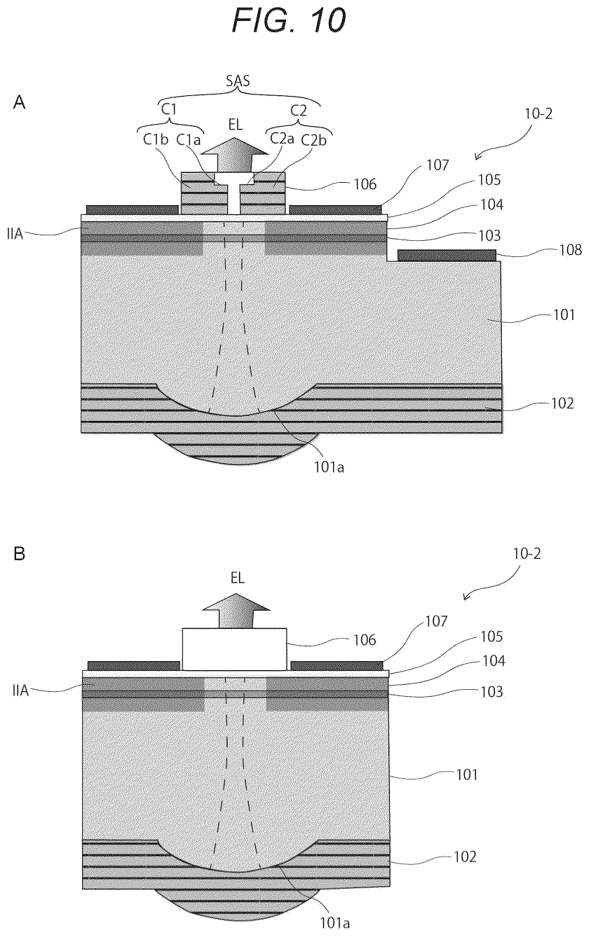

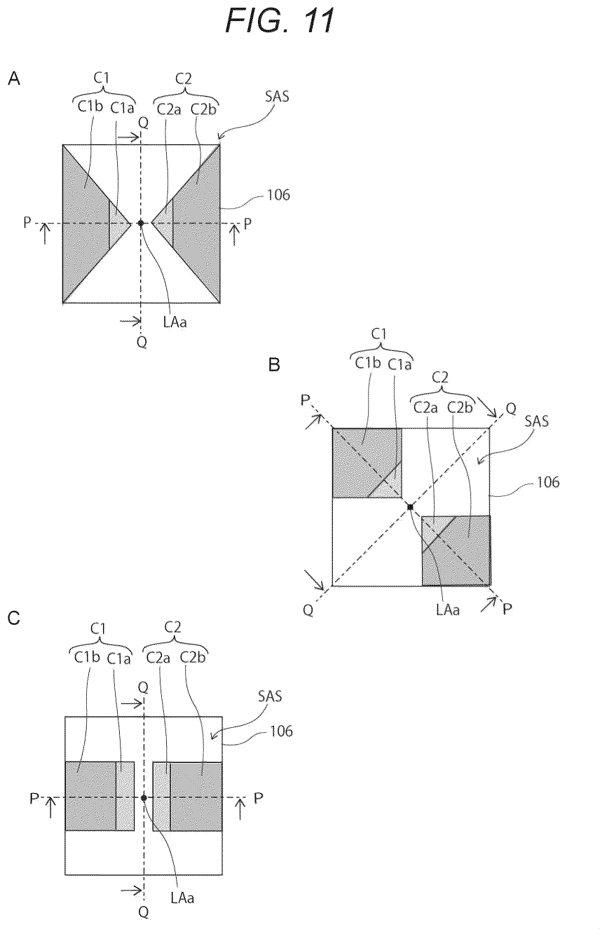

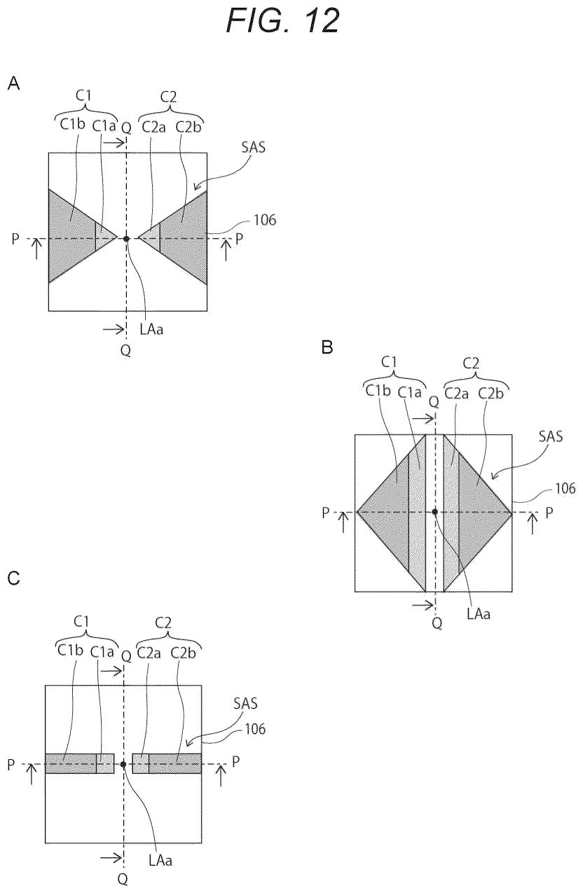

FIG. 10A is a cross-sectional view (part 1) of a surface emitting laser 10-2 according to Example 2 of the embodiment of the present technology. FIG. 10B is a cross-sectional view (part 2) of the surface emitting laser 10-2 according to Example 2 of the embodiment of the present technology. FIGS. 11A to 11C are views illustrating planar configuration examples 1 to 3 of the second reflecting mirror 106 of the surface emitting laser 10-2. FIGS. 12A to 12C are views illustrating planar configuration examples 4 to 6 of the second reflecting mirror 106 of the surface emitting laser 10-2. FIG. 10A is a cross-sectional view taken along line P-P in FIGS. 11A to 11C and FIGS. 12A to 12C. FIG. 10B is a cross-sectional view taken along line Q-Q in FIGS. 11A to 11C and FIGS. 12A to 12C.

The surface emitting laser 10-2 has a similar configuration to the surface emitting laser 10-1 according to Example 1 except that the thicknesses of the first and second configuration portions C1 and C2 of the stress application structure SAS (second reflecting mirror 106) change stepwise according to the distance from the position corresponding to the center LAa of the light emitting region LA.

In the surface emitting laser 10-2, the first configuration portion C1 of the stress application structure SAS (second reflecting mirror 106) has a thin film portion C1a relatively close to the position corresponding to the center LAa of the light emitting region LA and a normal film thickness portion C1b relatively far from the position corresponding to the center LAa of the light emitting region LA.

In the surface emitting laser 10-2, the second configuration portion C2 of the stress application structure SAS provided in the second reflecting mirror 106 has a thin film portion C2a relatively close to the position corresponding to the center LAa of the light emitting region LA and a normal film thickness portion C2b relatively far from the position corresponding to the center LAa of the light emitting region LA.

The thicknesses of the thin film portions C1a and C2a are the same, but may be different. The thicknesses of the normal film thickness portions C1b and C2b are substantially the same. Note that the normal film thickness portion is thicker than the thin film portion, and thus may be referred to as a “thick film portion”.

The surface emitting laser 10-2 can be manufactured by a similar manufacturing method to the method of manufacturing the surface emitting laser 10-1 according to Example 1 except that the second reflecting mirror 106 is half-etched at the time of forming the thin film portion.

According to the surface emitting laser 10-2, it is possible to obtain similar effects to those of the surface emitting laser 10-1 according to Example 1, and since the portion where the first and second configuration portions C1 and C2 are relatively close to the position corresponding to the center LAa of the light emitting region LA in the in-plane direction is thinned, the stress applied to the active layer 103 is reduced at the center LAa of the light emitting region LA and the vicinity thereof, and it is possible to reduce the influence on the laser characteristics.

Note that, in the surface emitting laser 10-2, the film thickness of each configuration portion of the stress application structure SAS is changed in one stage, but may be changed in a plurality of stages so as to be thinner toward the center LAa of the light emitting region LA, for example.

### 3. Surface Emitting Laser According to Example 3 of Embodiment of Present Technology

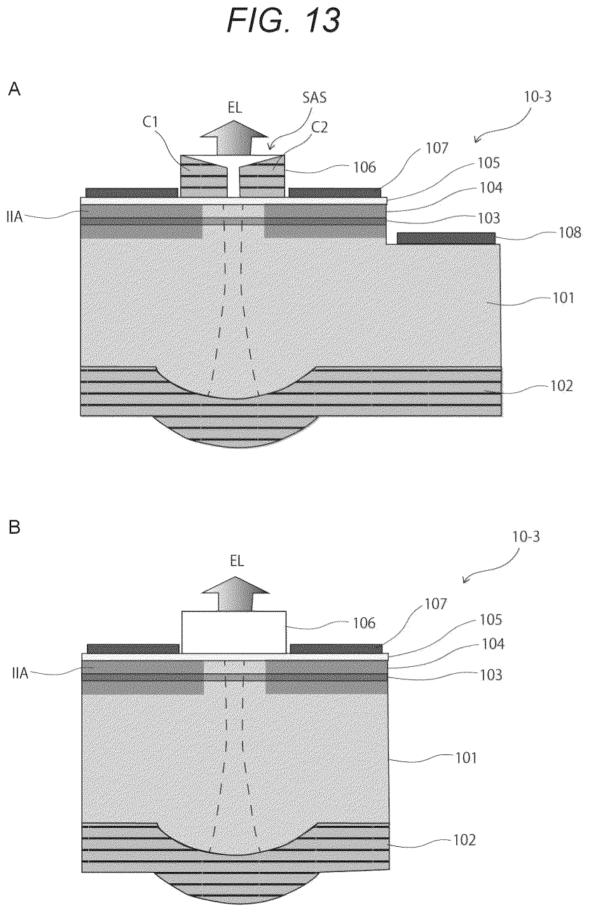

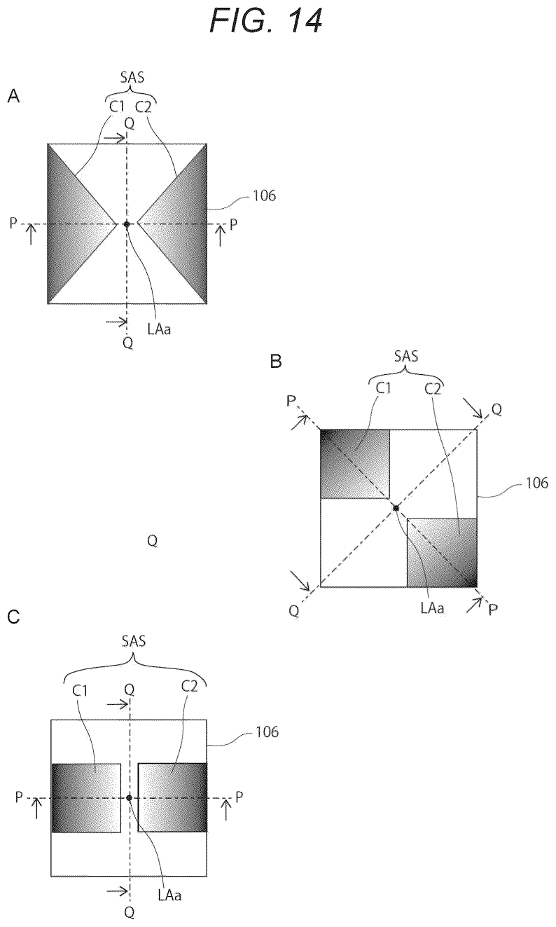

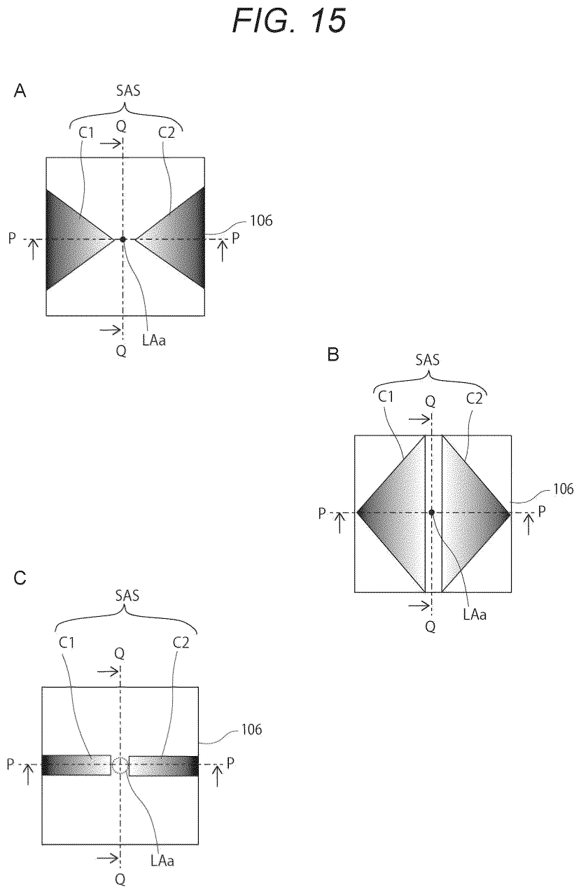

FIG. 13A is a cross-sectional view (part 1) of a surface emitting laser 10-3 according to Example 3 of the embodiment of the present technology. FIG. 13B is a cross-sectional view (part 2) of the surface emitting laser 10-3 according to Example 3 of the embodiment of the present technology. FIGS. 14A to 14C are views illustrating planar configuration examples 1 to 3 of the second reflecting mirror 106 of the surface emitting laser 10-3. FIGS. 15A to 15C are views illustrating planar configuration examples 4 to 6 of the second reflecting mirror 106 of the surface emitting laser 10-3. FIG. 13A is a cross-sectional view taken along line P-P in FIGS. 14A to 14C and FIGS. 15A to 15C. FIG. 13B is a cross-sectional view taken along line Q-Q in FIGS. 14A to 14C and FIGS. 15A to 15C.

The surface emitting laser 10-3 has a similar configuration to the surface emitting laser 10-1 according to Example 1 except that the thicknesses of the first and second configuration portions C1 and C2 of the stress application structure SAS (second reflecting mirror 106) gradually change according to the distance from the position corresponding to the center LAa of the light emitting region LA.

In the surface emitting laser 10-3, a longitudinal cross section of the first configuration portion C1 of the second reflecting mirror 106 as the stress application structure SAS is inclined so as to be thinner toward the position corresponding to the center LAa of the light emitting region LA. In FIGS. 14A to 14C and FIGS. 15A to 15C, in each configuration portion of the stress application structure SAS, the lighter the color, the thinner the thickness, and the darker the color, the thicker the thickness.

In the surface emitting laser 10-2, a longitudinal cross section of the second configuration portion C2 of the second reflecting mirror 106 as the stress application structure SAS is inclined so as to be thinner toward the position corresponding to the center LAa of the light emitting region LA.

The surface emitting laser 10-3 can be manufactured by a similar manufacturing method to the method of manufacturing the surface emitting laser 10-1 according to Example 1 except that the second reflecting mirror 106 is etched so that the etching depth gradually changes at the time of forming the first and second configuration portions C1 and C2.

According to the surface emitting laser 10-3, it is possible to obtain similar effects to those of the surface emitting laser 10-1 according to Example 1, and since the first and second configuration portions C1 and C2 become thinner as approaching the center LAa of the light emitting region LA, it is possible to reduce the stress applied to the active layer 103 as approaching the center LAa of the light emitting region LA, and eventually, it is possible to reduce the influence on the laser characteristics.

Note that, in the surface emitting laser 10-3, it is possible to appropriately change an inclination angle of the longitudinal cross section of each configuration portion of the stress application structure SAS in consideration of the magnitude of the applied stress and the influence on the laser characteristics.

### 4. Surface Emitting Laser According to Example 4 of Embodiment of Present Technology

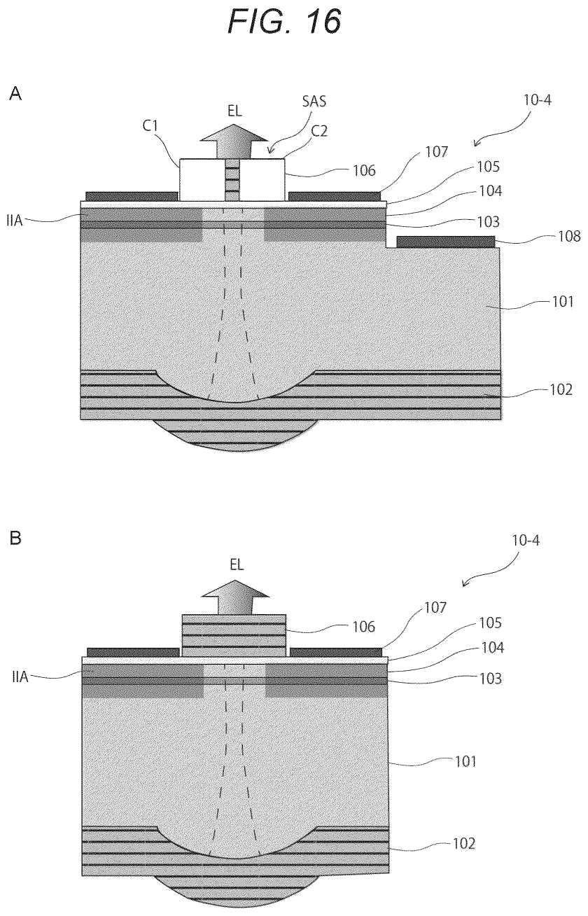

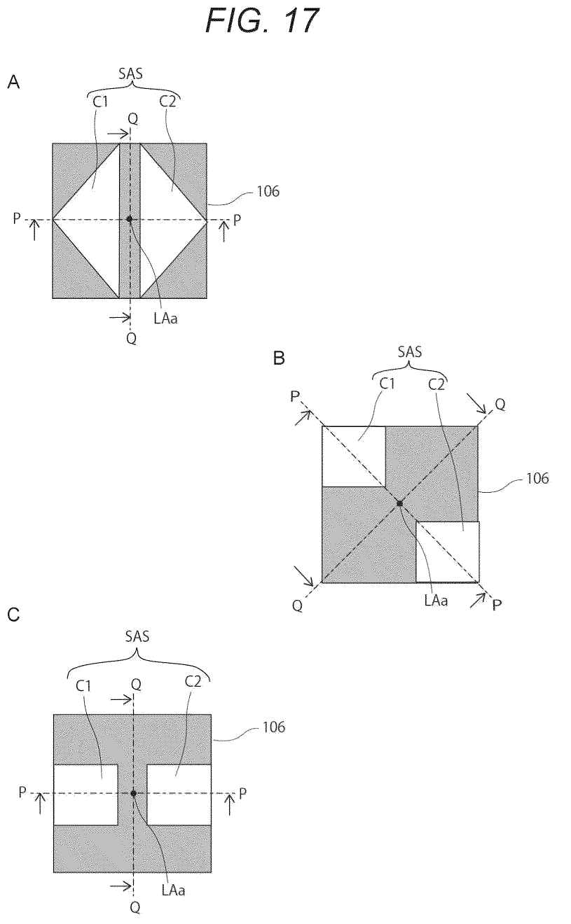

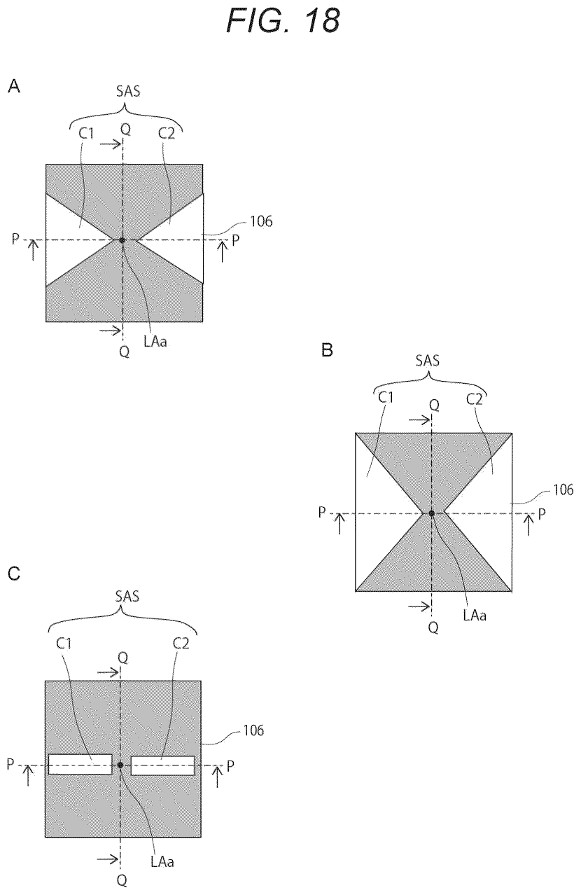

FIG. 16A is a cross-sectional view (part 1) of a surface emitting laser 10-4 according to Example 4 of the embodiment of the present technology. FIG. 16B is a cross-sectional view (part 2) of the surface emitting laser 10-4 according to Example 4 of the embodiment of the present technology. FIGS. 17A to 17C are views illustrating planar configuration examples 1 to 3 of the second reflecting mirror 106 of the surface emitting laser 10-4. FIGS. 18A to 18C are views illustrating planar configuration examples 4 to 6 of the second reflecting mirror 106 of the surface emitting laser 10-4. FIG. 16A is a cross-sectional view taken along line P-P in FIGS. 17A to 17C and FIGS. 18A to 18C. FIG. 16B is a cross-sectional view taken along line Q-Q in FIGS. 17A to 17C and FIGS. 18A to 18C.

The surface emitting laser 10-4 has a similar configuration to the surface emitting laser 10-1 according to Example 1 except that the stress application structure SAS is a void provided in the second reflecting mirror 106.

In the surface emitting laser 10-4, the first and second configuration portions C1 and C2 of the stress application structure SAS are a pair of voids sandwiching the center LAa of the light emitting region LA in plan view. Note that the first and second configuration portions C1 and C2 may be a pair of voids provided at positions sandwiching a part including the center LAa of the light emitting region LA in plan view, or may be a pair of voids provided at positions sandwiching the entire light emitting region LA. As an example, the pair of voids as the first and second configuration portions C1 and C2 is provided in the entire region in the thickness direction of the second reflecting mirror 106.

Also in the surface emitting laser 10-4, the stress application structure SAS has shape anisotropy in directions (for example, the P-P line direction and the Q-Q line direction in each of FIGS. 17A to 17C and FIGS. 18A to 18C) orthogonal to each other in the in-plane direction.

The pair of voids as the first and second configuration portions C1 and C2 are substantially point-symmetric with respect to the center LAa of the light emitting region LA in plan view (see FIGS. 17A to 17C and FIGS. 18A to 18C).

Examples of the shape in plan view of each of the pair of voids as the first and second configuration portions C1 and C2 include a polygon such as a triangle or a quadrangle, a circle, and an ellipse.

As the first and second configuration portions C1 and C2 are closer to the center LAa of the light emitting region LA, and the first and second configuration portions C1 and C2 are larger, the stress applied to the active layer 103 becomes larger. Note that the distance between each of the first and second configuration portions C1 and C2 and the center LAa of the light emitting region LA in plan view is preferably set to an appropriate distance that can reduce an influence on laser characteristics.

For example, in a case where the stress application direction (the arrangement direction of the first and second configuration portions C1 and C2, or the P-P line direction of FIGS. 17A to 17C and FIGS. 18A to 18C) by the stress application structure SAS is a tensile direction (a direction facing outward from the center LAa of the light emitting region LA), that is, in a case where a tensile strain in the P-P line direction occurs in the active layer 103, the polarization direction of the surface emitting laser 10-4 is controlled in the direction substantially perpendicular to the stress application direction (P-P line direction).

For example, in a case where the stress application direction (the arrangement direction of the first and second configuration portions C1 and C2, or the P-P line direction of FIGS. 17A to 17C and FIGS. 18A to 18C) by the stress application structure SAS is a compressive direction (a direction facing the center LAa of the light emitting region LA), that is, in a case where a compressive strain in the P-P line direction occurs in the active layer 103, the polarization direction of the surface emitting laser 10-4 is controlled in the direction substantially parallel to the stress application direction (P-P line direction).

The surface emitting laser 10-4 can be manufactured by a manufacturing method substantially similar to the method of manufacturing the surface emitting laser 10-1 according to Example 1.

According to the surface emitting laser 10-4, it is possible to obtain similar effects to those of the surface emitting laser 10-1 according to Example 1.

### 5. Surface Emitting Laser According to Example 5 of Embodiment of Present Technology

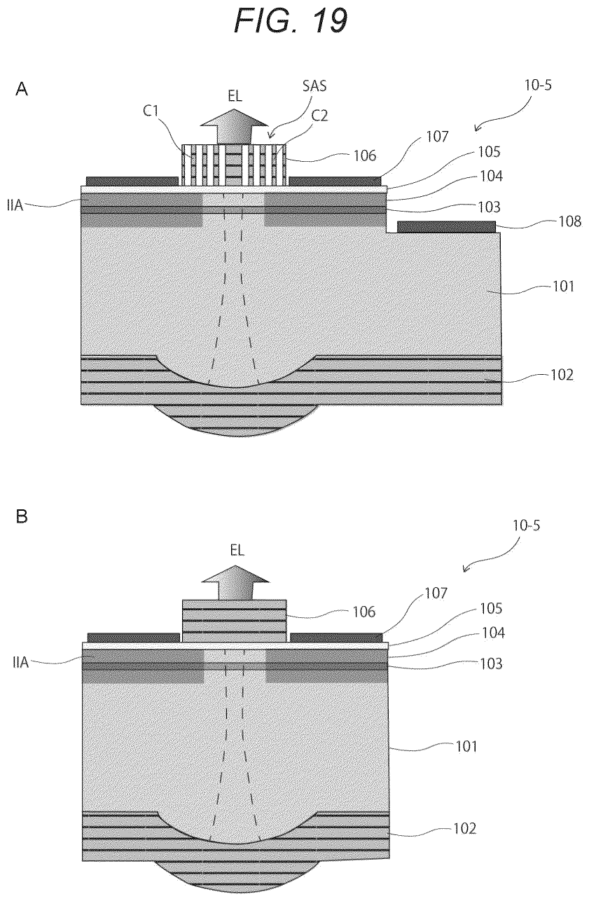

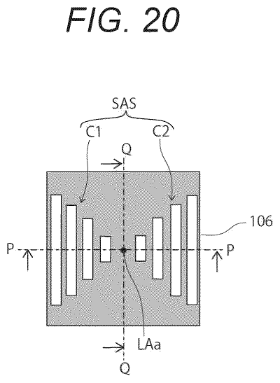

FIG. 19A is a cross-sectional view (part 1) of a surface emitting laser 10-5 according to Example 5 of the embodiment of the present technology. FIG. 19B is a cross-sectional view (part 2) of the surface emitting laser 10-5 according to Example 5 of the embodiment of the present technology. FIG. 20 is a view illustrating a planar configuration example of the second reflecting mirror 106 of the surface emitting laser 10-5.

The surface emitting laser 10-5 has a similar configuration to the surface emitting laser 10-1 according to Example 1 except that each configuration portion of the stress application structure SAS includes a plurality of voids provided in the second reflecting mirror 106.

In the surface emitting laser 10-5, the first and second configuration portions C1 and C2 of the stress application structure SAS are a pair of void groups provided at positions sandwiching the center LAa of the light emitting region LA in plan view. Each void group includes a plurality of (for example, four) voids. Note that the first and second configuration portions C1 and C2 may be a pair of void groups provided at positions sandwiching a part including the center LAa of the light emitting region LA in plan view, or may be a pair of void groups provided at positions sandwiching the entire light emitting region LA. As illustrated in FIG. 20 as an example, the plurality of voids of the void group as each configuration portion of the stress application structure SAS extends in the Q-Q line direction and is disposed in the P-P line direction. As an example, each void of the void group as each configuration portion of the stress application structure SAS is provided in the entire region in the thickness direction of the second reflecting mirror 106.

Also in the surface emitting laser 10-5, the stress application structure SAS has shape anisotropy in directions (for example, the P-P line direction and the Q-Q line direction in each of FIG. 20) orthogonal to each other in the in-plane direction.

The pair of void groups as the first and second configuration portions C1 and C2 are substantially point symmetric with respect to the center LAa of the light emitting region LA in plan view (see FIG. 20).

Examples of the shape in plan view of an envelope of each of the pair of void groups as the first and second configuration portions C1 and C2 include a polygon such as a triangle or a quadrangle, a circle, and an ellipse.

As the first and second configuration portions C1 and C2 are closer to the center LAa of the light emitting region LA, and the first and second configuration portions C1 and C2 are larger, the stress applied to the active layer 103 becomes larger. Note that the distance between each of the first and second configuration portions C1 and C2 and the center LAa of the light emitting region LA in plan view is preferably set to an appropriate distance that can reduce an influence on laser characteristics.

For example, in a case where the stress application direction (the arrangement direction of the first and second configuration portions C1 and C2, or the P-P line direction of FIG. 20) by the stress application structure SAS is a tensile direction (a direction facing outward from the center LAa of the light emitting region LA), that is, in a case where a tensile strain in the P-P line direction occurs in the active layer 103, the polarization direction of the surface emitting laser 10-5 is controlled in the direction substantially perpendicular to the stress application direction (P-P line direction).

For example, in a case where the stress application direction (the arrangement direction of the first and second configuration portions C1 and C2, or the P-P line direction of FIG. 20) by the stress application structure SAS is a compressive direction (a direction facing the center LAa of the light emitting region LA), that is, in a case where a compressive strain in the P-P line direction occurs in the active layer 103, the polarization direction of the surface emitting laser 10-5 is controlled in the direction substantially parallel to the stress application direction (P-P line direction).

The surface emitting laser 10-5 can be manufactured by a manufacturing method substantially similar to the method of manufacturing the surface emitting laser 10-1 according to Example 1.

According to the surface emitting laser 10-5, it is possible to obtain similar effects to those of the surface emitting laser 10-1 according to Example 1.

### 6. Surface Emitting Laser According to Example 6 of Embodiment of Present Technology

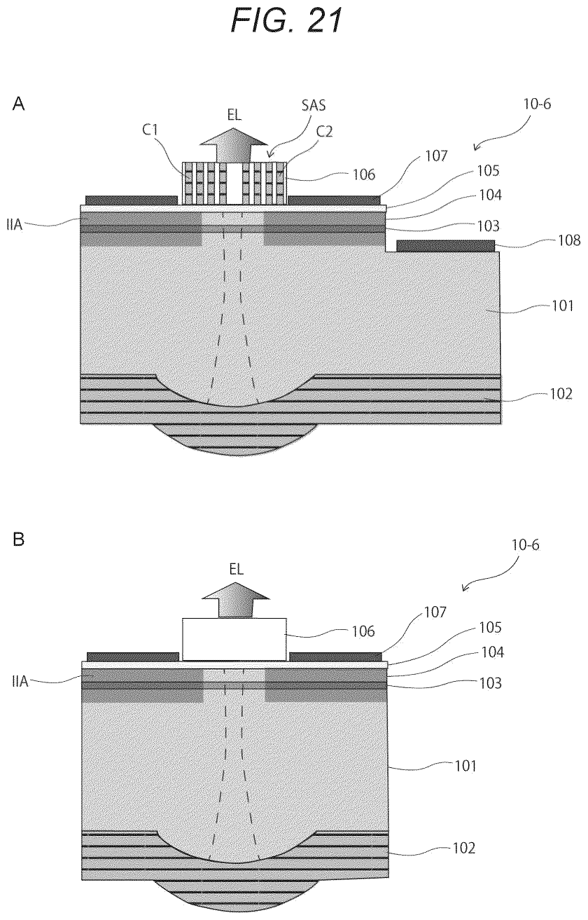

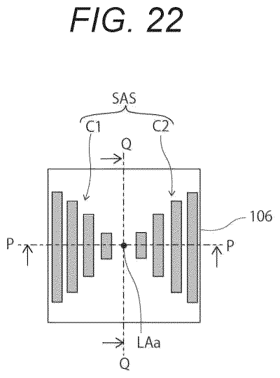

FIG. 21A is a cross-sectional view (part 1) of a surface emitting laser 10-6 according to Example 6 of the embodiment of the present technology. FIG. 21B is a cross-sectional view (part 2) of the surface emitting laser 10-6 according to Example 6 of the embodiment of the present technology. FIG. 22 is a view illustrating a planar configuration example of the second reflecting mirror 106 of the surface emitting laser 10-6.

The surface emitting laser 10-6 has a similar configuration to the surface emitting laser 10-1 according to Example 1 except that each configuration portion of the stress application structure SAS includes a plurality of ridges provided in the second reflecting mirror 106.

In the surface emitting laser 10-6, the first and second configuration portions C1 and C2 of the stress application structure SAS are a pair of ridge groups provided at positions sandwiching the center LAa of the light emitting region LA. Each ridge group includes a plurality of (for example, four) ridges. Note that the first and second configuration portions C1 and C2 may be a pair of ridge groups provided at positions sandwiching a part including the center LAa of the light emitting region LA in plan view, or may be a pair of ridge groups provided at positions sandwiching the entire light emitting region LA. As illustrated in FIG. 22 as an example, the plurality of voids of the void group as each configuration portion of the stress application structure SAS extends in the Q-Q line direction and is disposed in the P-P line direction. As an example, each ridge of the ridge group as each configuration portion of the stress application structure SAS is provided in the entire region in the thickness direction of the second reflecting mirror 106.

Also in the surface emitting laser 10-6, the stress application structure SAS has shape anisotropy in directions (for example, the P-P line direction and the Q-Q line direction in each of FIG. 22) orthogonal to each other in the in-plane direction.

The pair of ridge groups as the first and second configuration portions C1 and C2 are substantially point symmetric with respect to the center LAa of the light emitting region LA in plan view (see FIG. 22).

Examples of the shape in plan view of an envelope of each of the pair of ridge groups as the first and second configuration portions C1 and C2 include a polygon such as a triangle or a quadrangle, a circle, and an ellipse.

As the first and second configuration portions C1 and C2 are closer to the center LAa of the light emitting region LA, and the first and second configuration portions C1 and C2 are larger, the stress applied to the active layer 103 becomes larger. Note that the distance between each of the first and second configuration portions C1 and C2 and the center LAa of the light emitting region LA in plan view is preferably set to an appropriate distance that can reduce an influence on laser characteristics.

For example, in a case where the stress application direction (the arrangement direction of the first and second configuration portions C1 and C2, or the P-P line direction of FIG. 22) by the stress application structure SAS is a tensile direction (a direction facing outward from the center LAa of the light emitting region LA), that is, in a case where a tensile strain in the P-P line direction occurs in the active layer 103, the polarization direction of the surface emitting laser 10-6 is controlled in the direction substantially perpendicular to the stress application direction (P-P line direction).

For example, in a case where the stress application direction (the arrangement direction of the first and second configuration portions C1 and C2, or the P-P line direction of FIG. 22) by the stress application structure SAS is a compressive direction (a direction facing the center LAa of the light emitting region LA), that is, in a case where a compressive strain in the P-P line direction occurs in the active layer 103, the polarization direction of the surface emitting laser 10-6 is controlled in the direction substantially parallel to the stress application direction (P-P line direction).

The surface emitting laser 10-6 can be manufactured by a manufacturing method substantially similar to the method of manufacturing the surface emitting laser 10-1 according to Example 1.

According to the surface emitting laser 10-6, it is possible to obtain similar effects to those of the surface emitting laser 10-1 according to Example 1.

### 7. Surface Emitting Laser According to Example 7 of Embodiment of Present Technology

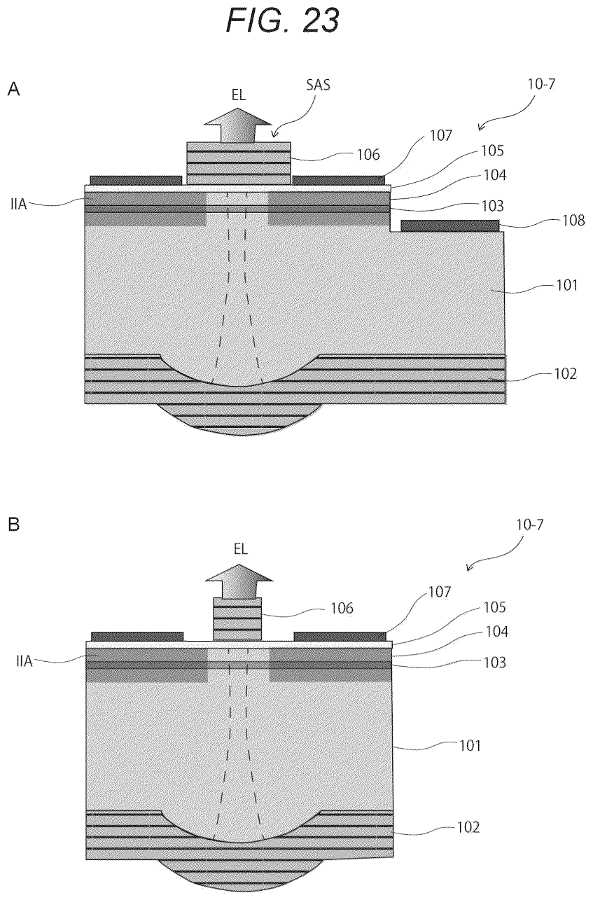

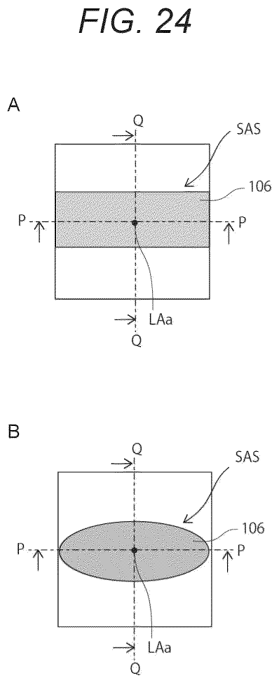

FIG. 23A is a cross-sectional view (part 1) of a surface emitting laser 10-7 according to Example 7 of the embodiment of the present technology. FIG. 23B is a cross-sectional view (part 2) of the surface emitting laser 10-7 according to Example 7 of the embodiment of the present technology. FIGS. 24A and 24B are views illustrating planar configuration examples 1 and 2 of the second reflecting mirror 106 of the surface emitting laser 10-7.

The surface emitting laser 10-7 has a similar configuration to the surface emitting laser 10-1 according to Example 1 except that the stress application structure SAS is the second reflecting mirror 106 having shape anisotropy.

In the surface emitting laser 10-7, the shape in plan view of the second reflecting mirror 106 as the stress application structure SAS is a shape having anisotropy such as a rectangular shape or an elliptical shape, for example.

In the surface emitting laser 10-7, the second reflecting mirror 106 as the stress application structure SAS has shape anisotropy in directions (for example, the P-P line direction and the Q-Q line direction in each of FIGS. 24A and 24B) orthogonal to each other in the in-plane direction.

The larger the second reflecting mirror 106 as the stress application structure SAS, the larger the stress applied to the active layer 103. In the second reflecting mirror 106 as the stress application structure SAS, the degree of shape anisotropy can be adjusted by adjusting a ratio of lengths in a longitudinal direction and a short direction, and eventually, the degree of concentration of the stress application direction to the active layer 103 into one direction can be adjusted.

For example, in a case where the stress application direction (the longitudinal direction of the second reflecting mirror 106, or the P-P line direction of FIG. 24A or 24B) by the stress application structure SAS is a tensile direction (a direction facing outward from the center LAa of the light emitting region LA), that is, in a case where a tensile strain in the P-P line direction occurs in the active layer 103, the polarization direction of the surface emitting laser 10-7 is controlled in the direction substantially perpendicular to the stress application direction (P-P line direction).

For example, in a case where the stress application direction (the longitudinal direction of the second reflecting mirror 106, or the P-P line direction of FIG. 24A or 24B) by the stress application structure SAS is a compressive direction (a direction facing the center LAa of the light emitting region LA), that is, in a case where a compressive strain in the P-P line direction occurs in the active layer 103, the polarization direction of the surface emitting laser 10-7 is controlled in the direction substantially parallel to the stress application direction (P-P line direction).

The surface emitting laser 10-7 can be manufactured by a manufacturing method substantially similar to the manufacturing method of the surface emitting laser 10-1 according to Example 1 except that the second reflecting mirror 106 is formed in an anisotropic shape.

According to the surface emitting laser 10-7, it is possible to further simplify the configuration although it is not possible to perform adjustment of the applied stress based on the position corresponding to the center LAa of the light emitting region LA.

### 8. Surface Emitting Laser According to Example 8 of Embodiment of Present Technology

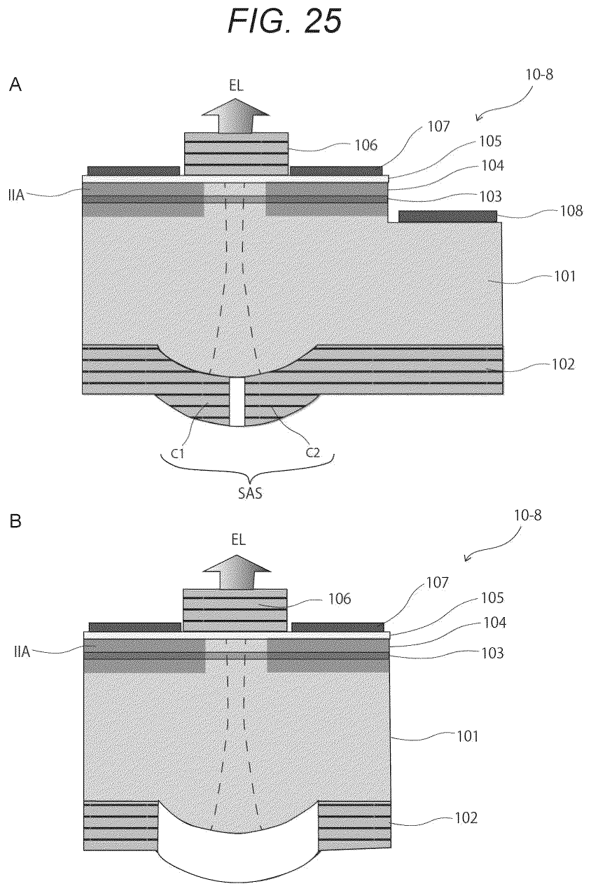

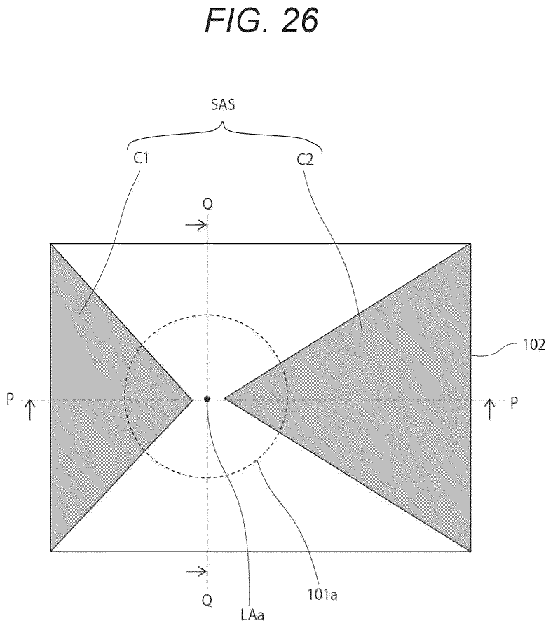

FIG. 25A is a cross-sectional view (part 1) of a surface emitting laser 10-8 according to Example 8 of the embodiment of the present technology. FIG. 25B is a cross-sectional view (part 2) of the surface emitting laser 10-8 according to Example 8 of the embodiment of the present technology. FIG. 26 is a view illustrating a planar configuration example of the first reflecting mirror 102 of the surface emitting laser 10-8.

The surface emitting laser 10-8 has a similar configuration to the surface emitting laser 10-1 according to Example 1 except that the first reflecting mirror 102 has the stress application structure SAS.

As an example, as illustrated in FIG. 26, the first reflecting mirror 102 has a rectangular shape in plan view, and the center of the concave mirror of the first reflecting mirror 102 (which is the center of the lens-shaped portion 101a and substantially coincides with the center LAa of the light emitting region LA) is eccentric with respect to the center of the first reflecting mirror 102.

Therefore, in the surface emitting laser 10-8, the shapes in plan view of the first and second configuration portions C1 and C2 of the stress application structure SAS are non-line-symmetric with respect to the Q-Q line (partially point-symmetric with respect to the center LAa of the light emitting region LA) according to the position of the concave mirror in the first reflecting mirror 102.

In the surface emitting laser 10-8, the first and second configuration portions C1 and C2 of the stress application structure SAS includes a dielectric multilayer film reflecting mirror, and the periphery thereof is a void.

Also in the surface emitting laser 10-8, the first and second configuration portions C1 and C2 of the stress application structure SAS can have various shapes in plan view, similarly to the surface emitting laser 10-1 according to Example 1.

The surface emitting laser 10-8 can be manufactured by a similar manufacturing method to the method of manufacturing the surface emitting laser 10-1 according to Example 1 except that the stress application structure SAS is formed in the first reflecting mirror 102.

According to the surface emitting laser 10-8, it is possible to obtain similar effects to those of the surface emitting laser 10-1 according to Example 1. Furthermore, it is possible to reduce the thickness (≈the resonator length) of the substrate 101 by the concave mirror structure. Therefore, it is possible to apply a large stress to the active layer 103 from the stress application structure SAS included in the first reflecting mirror 102, and it is possible to increase the amount of strain in the active layer 103.

### 9. Surface Emitting Laser According to Example 9 of Embodiment of Present Technology

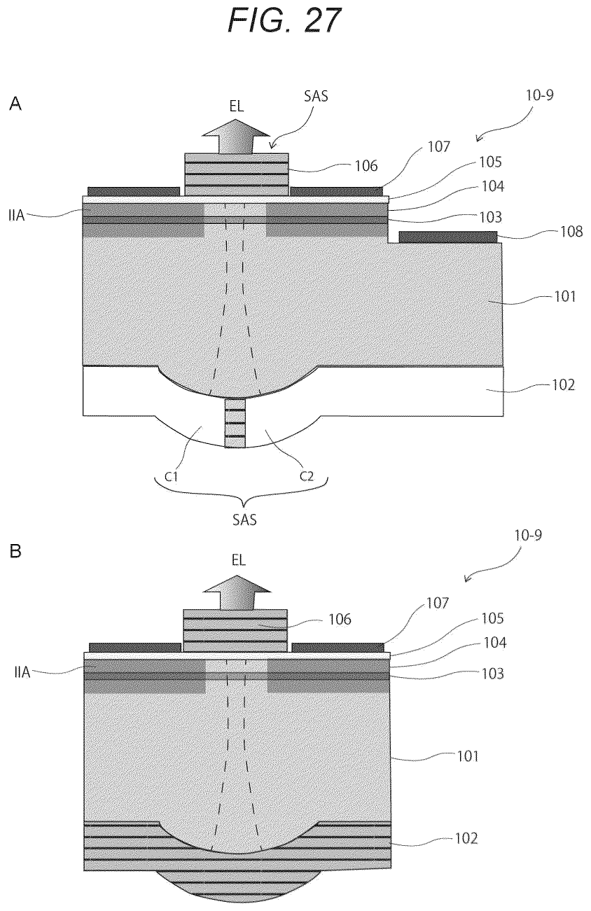

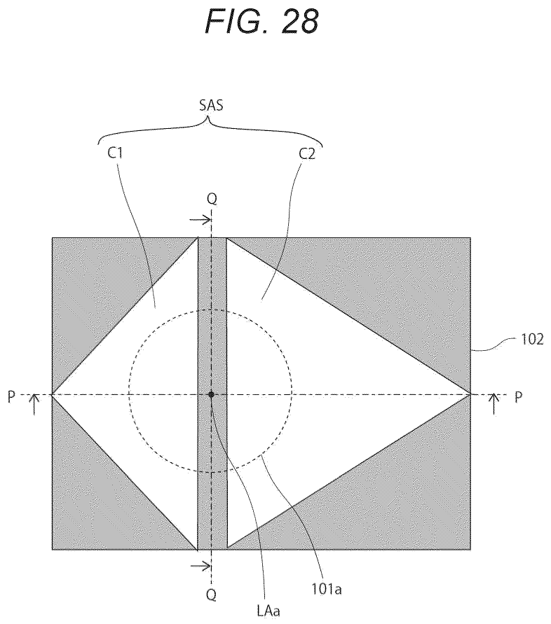

FIG. 27A is a cross-sectional view (part 1) of a surface emitting laser 10-9 according to Example 9 of the embodiment of the present technology. FIG. 27B is a cross-sectional view (part 2) of the surface emitting laser 10-9 according to Example 9 of the embodiment of the present technology. FIG. 28 is a view illustrating a planar configuration example of the first reflecting mirror 102 of the surface emitting laser 10-9.

The surface emitting laser 10-9 has a similar configuration to the surface emitting laser 10-8 according to Example 8 except that the first and second configuration portions C1 and C2 of the stress application structure SAS are voids provided in the first reflecting mirror 102.

In the surface emitting laser 10-9, each of the first and second configuration portions C1 and C2 of the stress application structure SAS is a void, and the periphery thereof is a dielectric multilayer film reflecting mirror.

In the surface emitting laser 10-9, similarly to the surface emitting laser 10-4 according to Example 4, the first and second configuration portions C1 and C2 of the stress application structure SAS can have various shapes.

The surface emitting laser 10-9 can be manufactured by a similar manufacturing method to the method of manufacturing the surface emitting laser 10-4 according to Example 4 except that the stress application structure SAS is formed in the first reflecting mirror 102.

According to the surface emitting laser 10-9, it is possible to obtain similar effects to those of the surface emitting laser 10-1 according to Example 1.

### 10. Surface Emitting Laser According to Example 10 of Embodiment of Present Technology

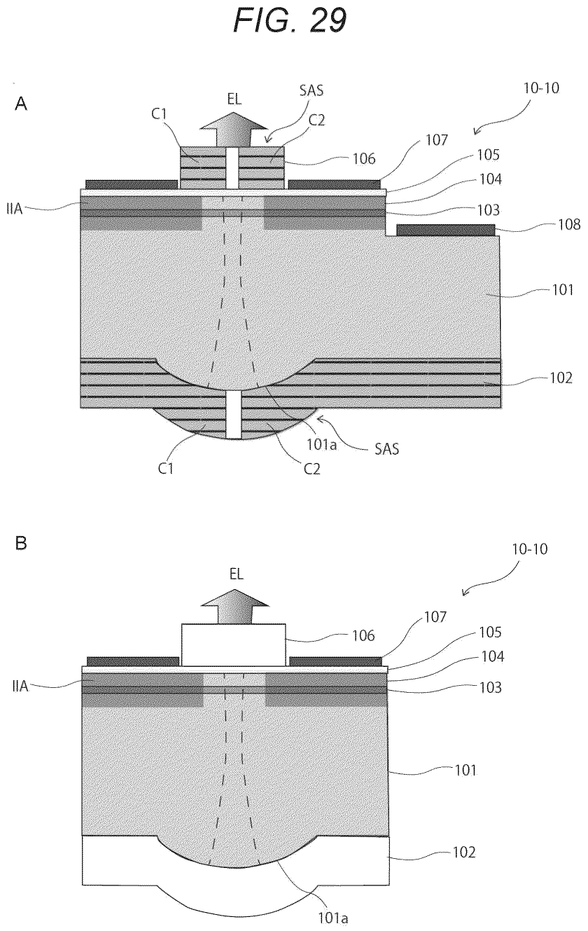

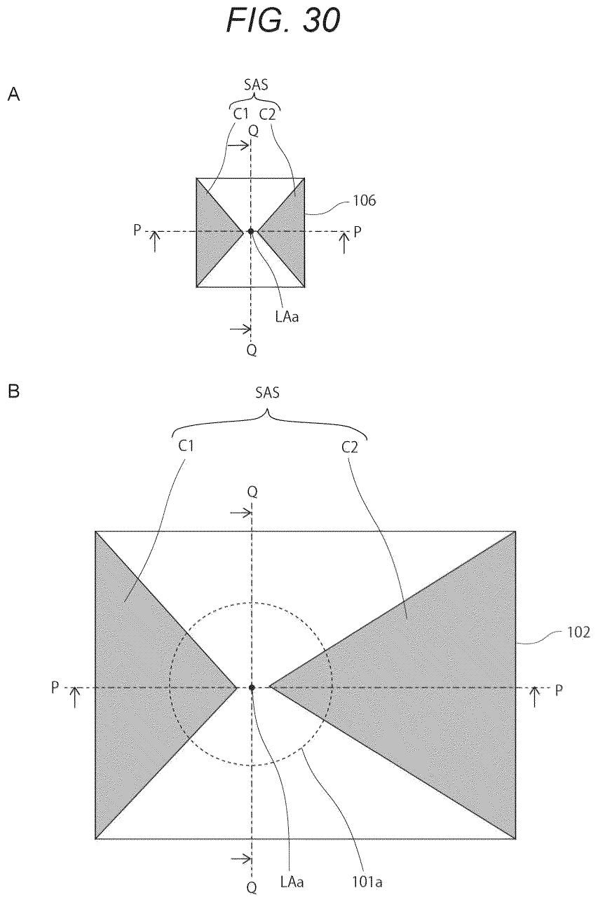

FIG. 29A is a cross-sectional view (part 1) of a surface emitting laser 10-10 according to Example 10 of the embodiment of the present technology. FIG. 29B is a cross-sectional view (part 2) of the surface emitting laser 10-10 according to Example 10 of the embodiment of the present technology. FIG. 30A is a view illustrating a planar configuration example of the second reflecting mirror 106 of the surface emitting laser 10-10. FIG. 30B is a view illustrating a planar configuration example of the first reflecting mirror 102 of the surface emitting laser 10-10.

The surface emitting laser 10-10 has a similar configuration to the surface emitting laser 10-1 according to Example 1 except that a plurality of (for example, two) stress application structures SAS is disposed at different positions in at least the stacking direction.

In the surface emitting laser 10-10, the plurality of stress application structures SAS includes first and second stress application structures on different sides in the stacking direction of the active layer 103, and the first and second stress application structures have different positive and negative signs (positive: tensile and negative: compressive) of applied stresses of the structures themselves. In this case, the angle formed by the stress application directions (the P-P line directions in FIGS. 30A and 30B) of the first and second stress application structures is preferably less than 45° in plan view, more preferably less than 30°, still more preferably less than 15°, and still more preferably less than 5°. Furthermore, in this case, an overlap ratio between the first and second stress application structures in plan view is preferably more than 50%, more preferably more than 65%, still more preferably more than 80%, and still more preferably more than 95%. Note that the “positive or negative sign of the applied stress” can also be referred to as the “polarity of the applied stress” or the “sign of the applied stress”.

In the surface emitting laser 10-10, each of the first and second reflecting mirrors 102 and 106 has the stress application structure SAS. As an example, the stress application structure SAS of the first reflecting mirror 102 is a first stress application structure, and the stress application structure SAS of the second reflecting mirror 106 is a second stress application structure.

As an example, each of the first and second configuration portions C1 and C2 of the first and second stress application structures includes a dielectric multilayer film reflecting mirror, and the periphery thereof is a void. In the first and second stress application structures, the positive and negative signs of the applied stresses are the same, and the arrangement direction (stress application directions) of the first and second configuration portions C1 and C2 is in a parallel state (see FIGS. 30A and 30B), or is in a relatively rotated state by an angle less than ±45° from the parallel state. In this case, a synergistic effect can be enhanced more than an effect of offsetting the stress applied to the active layer 103 in at least one direction. In particular, as the arrangement direction of the first and second configuration portions C1 and C2 of each of the first and second stress application structures is closer to parallel, the stress application directions of the first and second stress application structures SAS are closer to parallel, and the synergistic effect of the stress applied to the active layer 103 can be further enhanced, and eventually, polarization controllability can be further improved.

Also in the surface emitting laser 10-10, the first and second configuration portions C1 and C2 of the second stress application structure can have various shapes, similarly to the surface emitting laser 10-1 according to Example 1, and the first and second configuration portions C1 and C2 of the first stress application structure can have various shapes, similarly to the surface emitting laser 10-4 according to Example 4.

The surface emitting laser 10-10 can be manufactured by a similar manufacturing method to the method of manufacturing the surface emitting laser 10-1 according to Example 1 except that the stress application structure SAS is formed in the first and second reflecting mirrors 102 and 106.

According to the surface emitting laser 10-10, it is possible to obtain similar effects to those of the surface emitting laser 10-1 according to Example 1, and it is possible to adjust the amount of strain in the active layer 103 by providing the stress application structures in the plurality of layers, and eventually, it is possible to improve polarization controllability.

Note that, in the surface emitting laser 10-10, the first and second stress application structures are provided in the first and second reflecting mirrors 102 and 106, respectively, but the example is not limited thereto, and the first stress application structure may be provided in a layer (for example, any one of the first reflecting mirror 102, the substrate 101, and the cathode electrode 108) on one side in the stacking direction of the active layer 103, and the second stress application structure may be provided in a layer (for example, any one of the cladding layer 104, the transparent conductive film 105, the second reflecting mirror 106, and the anode electrode 107) on another side in the stacking direction of the active layer 103. Also in this case, similar discussion to that in Example 10 is established.

### 11. Surface Emitting Laser According to Example 11 of Embodiment of Present Technology

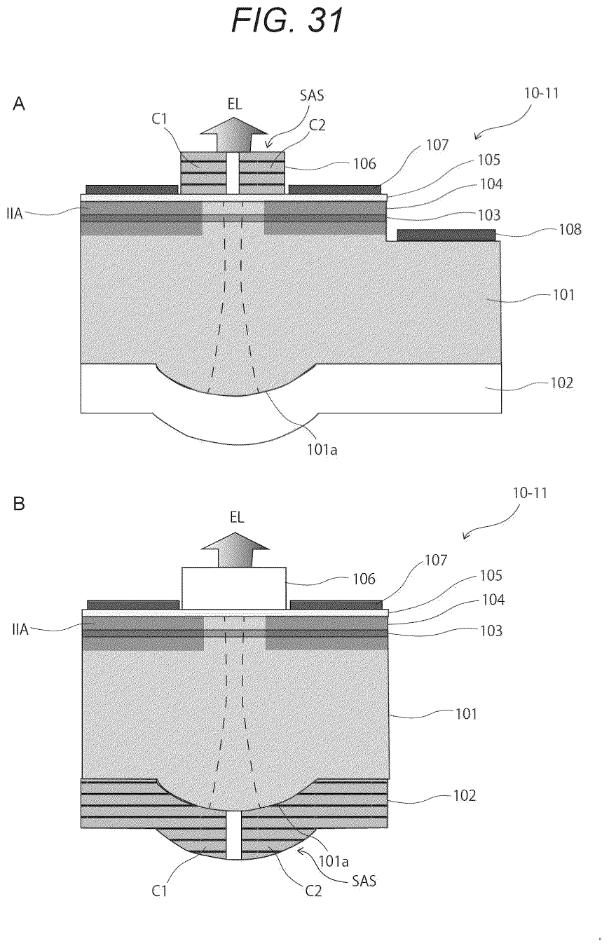

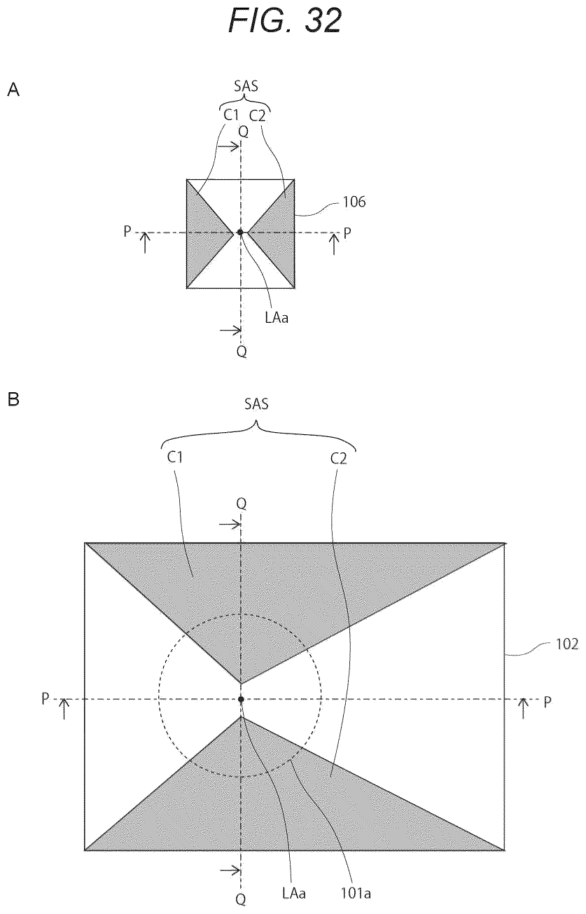

FIG. 31A is a cross-sectional view (part 1) of a surface emitting laser 10-11 according to Example 11 of the embodiment of the present technology. FIG. 31B is a cross-sectional view (part 2) of the surface emitting laser 10-11 according to Example 11 of the embodiment of the present technology. FIG. 32A is a view illustrating a planar configuration example of the second reflecting mirror 106 of the surface emitting laser 10-11. FIG. 32B is a view illustrating a planar configuration example of the first reflecting mirror 102 of the surface emitting laser 10-11.

The surface emitting laser 10-11 has a similar configuration to the surface emitting laser 10-10 according to Example 10 except for the angle formed by the stress application directions of the plurality of stress application structures SAS in plan view.

In the surface emitting laser 10-11, the plurality of stress application structures SAS includes first and second stress application structures on different sides in the stacking direction of the active layer 103, and the first and second stress application structures have the same positive and negative signs (positive: tensile and negative: compressive) of the applied stresses of the structures themselves. In this case, the angle formed by the stress application directions (the P-P line direction in FIG. 32A and the Q-Q line direction in FIG. 32B of the first and second stress application structures is preferably more than 45° in plan view, more preferably more than 60°, still more preferably more than 75°, and still more preferably more than 85°. Furthermore, in this case, the overlap ratio between the first and second stress application structures in plan view is preferably less than 50%, more preferably less than 35%, still more preferably less than 20%, and still more preferably less than 5%. Note that the “positive or negative sign of the applied stress” can also be referred to as the “polarity of the applied stress” or the “sign of the applied stress”.

In the surface emitting laser 10-11, each of the first and second reflecting mirrors 102 and 106 has the stress application structure SAS. As an example, the stress application structure SAS of the first reflecting mirror 102 is the first stress application structure, and the stress application structure SAS of the second reflecting mirror 106 is the second stress application structure.

As an example, each of the first and second configuration portions C1 and C2 of the first and second stress application structures includes a dielectric multilayer film reflecting mirror, and the periphery thereof is a void. In the first and second stress application structures, the positive and negative signs of the applied stresses are different, and the arrangement direction (stress application directions) of the first and second configuration portions C1 and C2 is in a perpendicular state in plan view (see FIGS. 32A and 32B), or is in a relatively rotated state by an angle less than ±45° from the perpendicular state. In this case, a synergistic effect can be enhanced more than an effect of offsetting the stress applied to the active layer 103 in at least one direction. In particular, as the arrangement direction of the first and second configuration portions C1 and C2 of each of the first and second stress application structures is closer to perpendicular, the stress application directions of the first and second stress application structures SAS are closer to perpendicular, and the synergistic effect of the stress applied to the active layer 103 can be further enhanced, and eventually, polarization controllability can be further improved.

Also in the surface emitting laser 10-11, the first and second configuration portions C1 and C2 of the second stress application structure can have various shapes, similarly to the surface emitting laser 10-1 according to Example 1, and the first and second configuration portions C1 and C2 of the first stress application structure can have various shapes, similarly to the surface emitting laser 10-4 according to Example 4.

The surface emitting laser 10-11 can be manufactured by a similar manufacturing method to the method of manufacturing the surface emitting laser 10-1 according to Example 1 except that the stress application structure SAS is formed in the first and second reflecting mirrors 102 and 106.

According to the surface emitting laser 10-11, it is possible to obtain similar effects to those of the surface emitting laser 10-1 according to Example 1, and it is possible to adjust the amount of strain in the active layer 103 by providing the stress application structures in the plurality of layers, and eventually, it is possible to improve polarization controllability.

Note that, in the surface emitting laser 10-11, the first and second stress application structures are provided in the first and second reflecting mirrors 102 and 106, but the example is not limited thereto, and the first stress application structure may be provided in a layer (for example, any one of the first reflecting mirror 102, the substrate 101, and the cathode electrode 108) on one side in the stacking direction of the active layer 103, and the second stress application structure may be provided in a layer (for example, any one of the cladding layer 104, the transparent conductive film 105, the second reflecting mirror 106, and the anode electrode 107) on another side in the stacking direction of the active layer 103. Also in this case, similar discussion to that in Example 11 is established.

As can be seen from the description of Example 10 and Example 11, in the case where a plurality of stress application structures is provided, it is possible to adjust the amount of strain in the active layer 103 by adjusting the stress application directions of the plurality of stress application structures SAS regardless of the positive or negative sign of the applied stresses of the stress application structures.

### 12. Surface Emitting Laser According to Example 12 of Embodiment of Present Technology

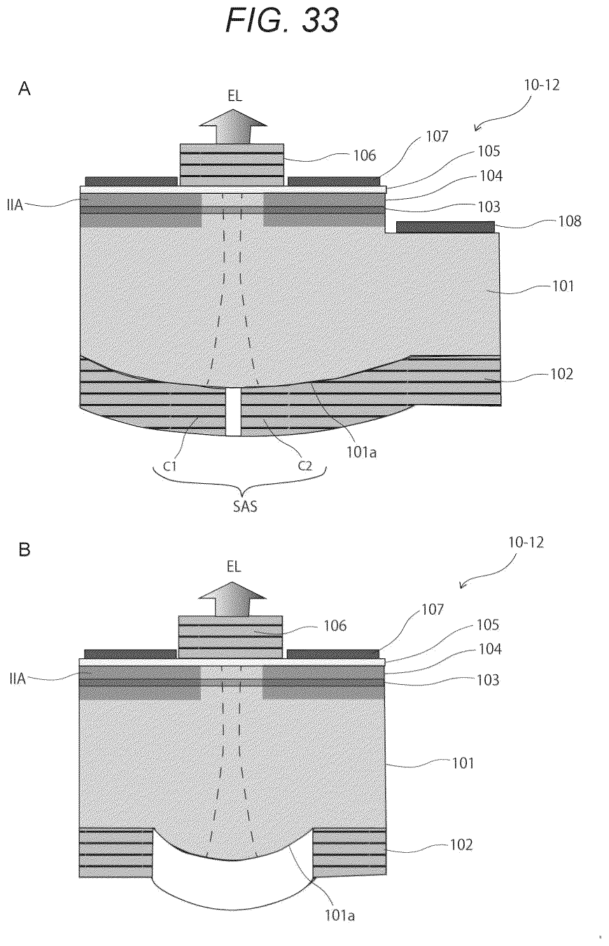

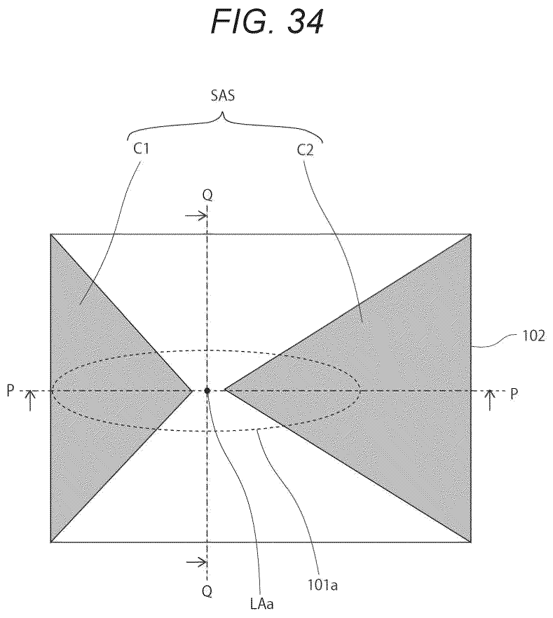

FIG. 33A is a cross-sectional view (part 1) of a surface emitting laser 10-12 according to Example 12 of the embodiment of the present technology. FIG. 33B is a cross-sectional view (part 2) of the surface emitting laser 10-12 according to Example 12 of the embodiment of the present technology. FIG. 34 is a view illustrating a planar configuration example of the first reflecting mirror 102 of the surface emitting laser 10-12.

The surface emitting laser 10-12 has a similar configuration to the surface emitting laser 10-8 according to Example 8 except that the lens-shaped portion 101a and the shape in plan view of the concave mirror of the first reflecting mirror 102 are elliptical.

In the surface emitting laser 10-12, it is preferable that the major axis direction of the ellipse that is the shape in plan view of the lens-shaped portion 101a and the concave mirror of the first reflecting mirror 102 and the stress application direction of the stress application structure SAS are parallel to each other, but may form an angle of less than 45° in plan view.

The surface emitting laser 10-12 can be manufactured by a similar manufacturing method to the method of manufacturing the surface emitting laser 10-8 according to Example 8 except that the lens-shaped portion 101a and the first reflecting mirror 102 are formed in an elliptical shape in plan view.

According to the surface emitting laser 10-12, it is possible to obtain effects similar to those of the surface emitting laser 10-1 according to Example 1, and it is possible to impart anisotropy to the diffraction loss inside the resonator by the elliptical concave mirror. Therefore, it is possible to further improve polarization controllability by combining the anisotropy with the shape anisotropy of the stress application structure SAS.

### 13. Surface Emitting Laser According to Example 13 of Embodiment of Present Technology

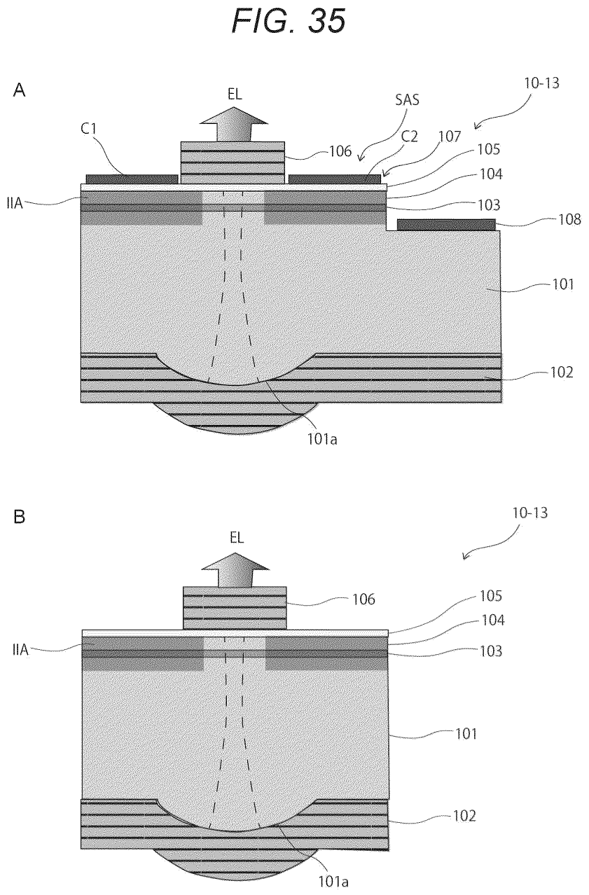

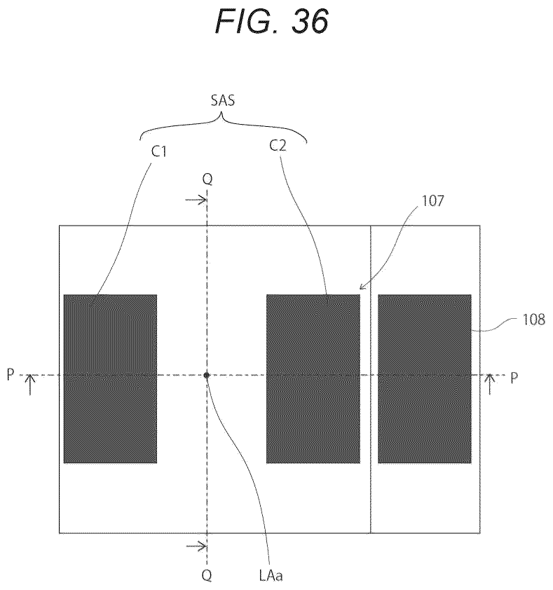

FIG. 35A is a cross-sectional view (part 1) of a surface emitting laser 10-13 according to Example 13 of the embodiment of the present technology. FIG. 35B is a cross-sectional view (part 2) of the surface emitting laser 10-13 according to Example 13 of the embodiment of the present technology. FIG. 36 is a view illustrating a planar configuration example of the anode electrode 107 and the cathode electrode 108 of the surface emitting laser 10-12. FIG. 35A is a cross-sectional view taken along line P-P in FIG. 36. FIG. 35B is a cross-sectional view taken along line Q-Q in FIG. 36.

The surface emitting laser 10-13 has a similar configuration to the surface emitting laser 10-1 according to Example 1 except that the anode electrode 107 provided in the second structure has the stress application structure SAS.

In the surface emitting laser 10-13, the anode electrode 107 as the stress application structure SAS has a pair of electrode portions to be the first and second configuration portions C1 and C2. The pair of electrode portions as the first and second configuration portions C1 and C2 are disposed on the transparent conductive film 105 so as to face each other with the center LAa of the light emitting region LA interposed therebetween in plan view. That is, the anode electrode 107 has shape anisotropy. The stress application direction of the anode electrode 107 as the stress application structure SAS is an arrangement direction of the pair of electrode portions as the first and second configuration portions C1 and C2 (P-P line direction in FIG. 36). The anode electrode 107 as the stress application structure SAS can apply a residual stress at the time of film formation of the electrode material to the active layer 103.

The surface emitting laser 10-13 can be manufactured by a similar manufacturing method to the method of manufacturing the surface emitting laser 10-1 according to Example 1 except that the pair of electrode portions of the anode electrode 107 is formed.

According to the surface emitting laser 10-13, it is possible to obtain substantially similar effects to those of the surface emitting laser 10-1 according to Example 1.

### 14. Surface Emitting Laser According to Example 14 of Embodiment of Present Technology

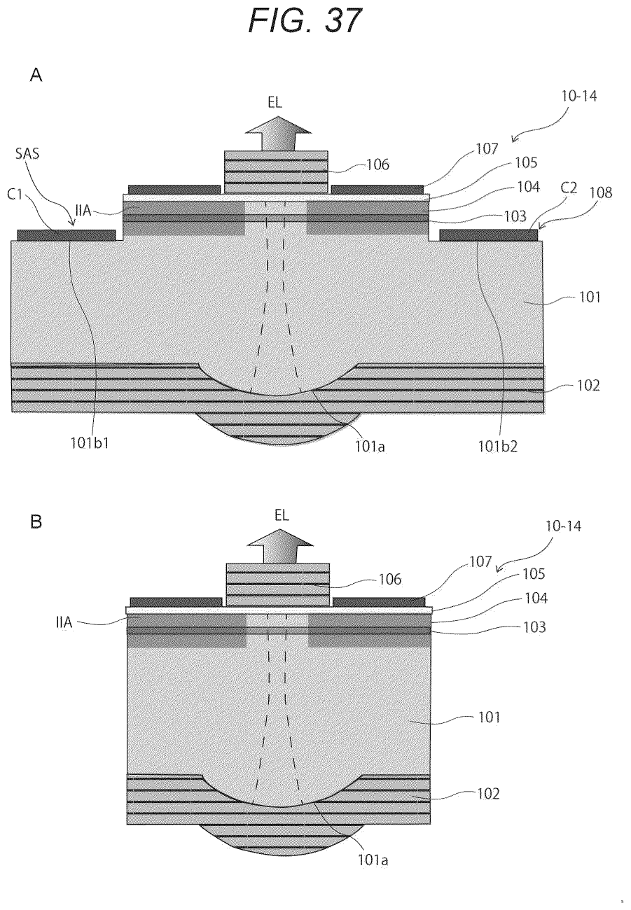

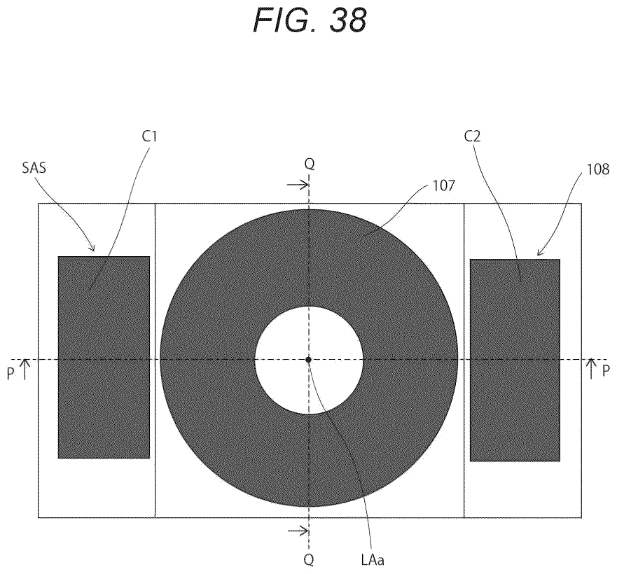

FIG. 37A is a cross-sectional view (part 1) of a surface emitting laser 10-14 according to Example 14 of the embodiment of the present technology. FIG. 37B is a cross-sectional view (part 2) of the surface emitting laser 10-14 according to Example 14 of the embodiment of the present technology. FIG. 38 is a view illustrating a planar configuration example of the anode electrode 107 and the cathode electrode 108 of the surface emitting laser 10-14. FIG. 37A is a cross-sectional view taken along line P-P in FIG. 38. FIG. 37B is a cross-sectional view taken along line Q-Q in FIG. 38.

The surface emitting laser 10-14 has a similar configuration to the surface emitting laser 10-1 according to Example 1 except that the cathode electrode 108 provided in the first structure has the stress application structure SAS. The shape in plan view of the anode electrode 107 is, for example, an isotropic shape (for example, a ring shape).

In the surface emitting laser 10-14, the cathode electrode 108 as the stress application structure SAS has a pair of electrode portions to be the first and second configuration portions C1 and C2. The pair of electrode portions as the first and second configuration portions C1 and C2 are disposed on a pair of electrode installation portions 101b1 and 101b2 so as to face each other with the center LAa of the light emitting region LA interposed therebetween in plan view. That is, the cathode electrode 108 has shape anisotropy. The stress application direction of the cathode electrode 108 as the stress application structure SAS is an arrangement direction of the pair of electrode portions as the first and second configuration portions C1 and C2 (P-P line direction in FIG. 38). The cathode electrode 108 as the stress application structure SAS can apply a residual stress at the time of film formation of the electrode material to the active layer 103.

The surface emitting laser 10-14 can be manufactured by a similar manufacturing method to the method of manufacturing the surface emitting laser 10-1 according to Example 1 except that the pair of electrode portions of the cathode electrode 108 is formed.

According to the surface emitting laser 10-14, it is possible to obtain substantially similar effects to those of the surface emitting laser 10-1 according to Example 1.

### 15. Surface Emitting Laser According to Example 15 of Embodiment of Present Technology

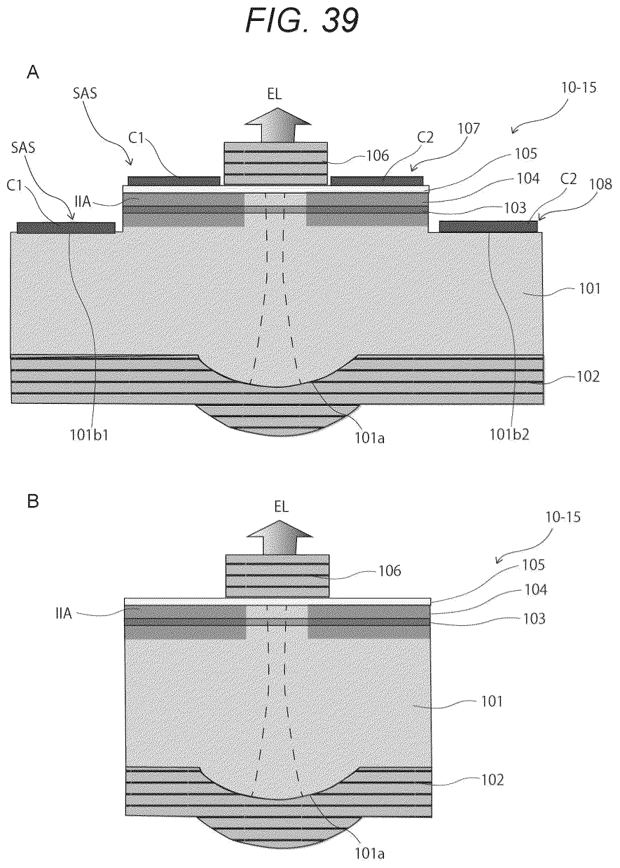

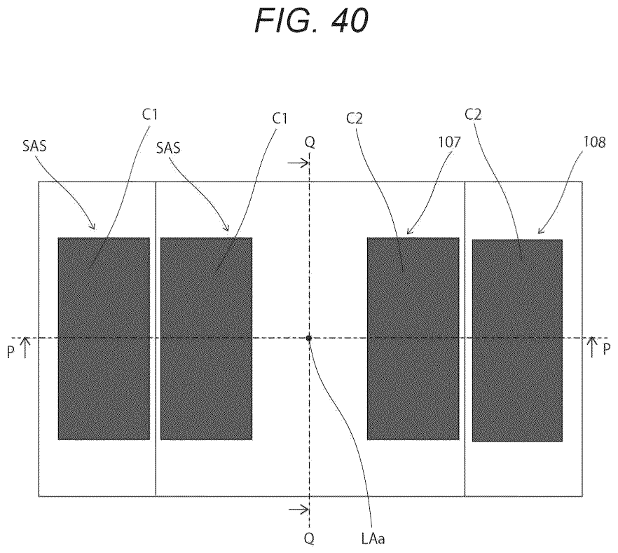

FIG. 39A is a cross-sectional view (part 1) of a surface emitting laser 10-15 according to Example 15 of the embodiment of the present technology. FIG. 39B is a cross-sectional view (part 2) of the surface emitting laser 10-15 according to Example 15 of the embodiment of the present technology. FIG. 40 is a view illustrating a planar configuration example of the anode electrode 107 and the cathode electrode 108 of the surface emitting laser 10-15. FIG. 39A is a cross-sectional view taken along line P-P in FIG. 40. FIG. 39B is a cross-sectional view taken along line Q-Q in FIG. 40.

The surface emitting laser 10-15 has a similar configuration to the surface emitting laser 10-1 according to Example 1 except that a plurality of (for example, two) stress application structures SAS is disposed at different positions in at least the stacking direction (for example, the stacking direction and the in-plane direction).

In the surface emitting laser 10-15, the plurality of stress application structures SAS includes the first and second stress application structures on different sides in the stacking direction of the active layer 103, and in the first and second stress application structures, the positive and negative signs of the applied stresses of the structures themselves are different, and the angle formed by the stress application directions of the first and second stress application Structures in plan view is less than 45°.

Specifically, in the surface emitting laser 10-15, the anode electrode 107 provided in the second structure has the first stress application structure, and the cathode electrode 108 provided in the first structure has the second stress application structure.

In the surface emitting laser 10-15, each of the anode electrode 107 as the first stress application structure and the cathode electrode 108 as the second stress application structure has the pair of electrode portions to be the first and second configuration portions C1 and C2.

The pair of electrode portions as the first and second configuration portions C1 and C2 of the anode electrode 107 is disposed on the transparent conductive film 105 so as to face each other with the center LAa of the light emitting region LA interposed therebetween. That is, the anode electrode 107 has shape anisotropy. The stress application direction of the anode electrode 107 as the first stress application structure is the arrangement direction of the pair of electrode portions as the first and second configuration portions C1 and C2 (P-P line direction in FIG. 40). The anode electrode 107 as the first stress application structure can apply a residual stress at the time of film formation of the electrode material to the active layer 103.

The pair of electrode portions as the first and second configuration portions C1 and C2 of the cathode electrode 108 is disposed on a pair of the electrode installation portions 101b1 and 101b2 so as to face each other with the center LAa of the light emitting region LA interposed therebetween. That is, the cathode electrode 108 has shape anisotropy. The stress application direction of the cathode electrode 108 as the second stress application structure is an arrangement direction of the pair of electrode portions as the first and second configuration portions C1 and C2 (P-P line direction in FIG. 40). The cathode electrode 108 as the second stress application structure can apply a residual stress at the time of film formation of the electrode material to the active layer 103.

In the surface emitting laser 10-15, since the anode electrode 107 (first stress application structure) and the cathode electrode 108 (second stress application structure) are on different sides in the stacking direction of the active layer 103, the positive and negative signs of the applied stresses are different, and the angle formed by the stress application directions is less than 45° in plan view, the stress for controlling the polarization direction to the same direction can be synergistically applied to the active layer 103. Note that, in this case, as the stress application directions of the anode electrode 107 and the cathode electrode 108 in plan view are closer to parallel (the angle formed by the stress application directions is closer to 0°), the stress can be more synergistically applied to the active layer 103, which is preferable.

On the other hand, in a case where the anode electrode 107 (first stress application structure) and the cathode electrode 108 (second stress application structure) are on different sides in the stacking direction of the active layer 103, and the positive and negative signs of the applied stresses are the same, the angle formed by the stress application directions of the anode electrode 107 and the cathode electrode 108 is preferably more than 45°. In this case, the stress for controlling the polarization direction to the same direction can be synergistically applied to the active layer 103. Note that, in this case, as the stress application directions of the anode electrode 107 and the cathode electrode 108 in plan view are closer to perpendicular (the angle formed by the stress application directions is closer to 90°), the stress can be more synergistically applied to the active layer 103, which is preferable.

The surface emitting laser 10-15 can be manufactured by a similar manufacturing method to the method of manufacturing the surface emitting laser 10-1 according to Example 1 except that the pair of electrode portions of the anode electrode 107 and the pair of electrode portions of the cathode electrode 108 are formed.

According to the surface emitting laser 10-15, it is possible to obtain substantially similar effects to those of the surface emitting laser 10-1 according to Example 1.

### Method 1 of Controlling Polarization Direction by Stress Application Structure

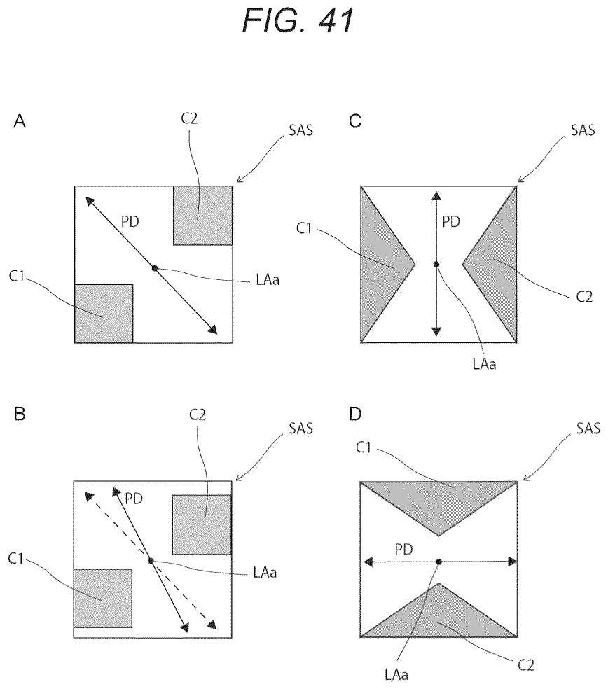

FIGS. 41A to 41D are views for describing a method of controlling the polarization direction by the stress application structure SAS that causes a tensile strain in the active layer 103. As illustrated in FIGS. 41A to 41D, in the stress application structure SAS (applied stress is positive) that causes a tensile strain in the active layer 103, a polarization direction PD is controlled in a direction substantially perpendicular to the stress application direction that is the arrangement direction of the first and second configuration portions C1 and C2. Therefore, the polarization direction PD can be controlled in a desired direction by setting the arrangement direction of the first and second configuration portions C1 and C2 to a direction perpendicular to the desired polarization direction PD. For example, the polarization direction PD can be adjusted by changing the arrangement of the first and second configuration portions C1 and C2 between the state of FIG. 41A and the state of FIG. 41B. That is, the polarization direction to be controlled can be adjusted by changing the direction of the strain to be applied to the active layer 103.

### Method 2 of Controlling Polarization Direction by Stress Application Structure

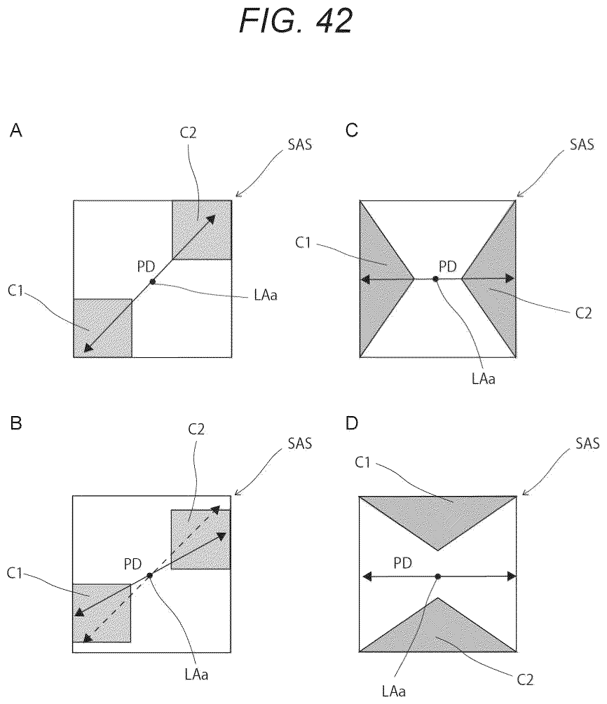

FIGS. 42A to 42D are views for describing a method of controlling the polarization direction by the stress application structure SAS that causes a compressive strain in the active layer 103. As illustrated in FIGS. 42A to 42D, in the stress application structure SAS (applied stress is negative) that causes a compressive strain in the active layer 103, the polarization direction PD is controlled in a direction substantially parallel to the stress application direction that is the arrangement direction of the first and second configuration portions C1 and C2. Therefore, the polarization direction PD can be controlled in a desired direction by setting the arrangement direction of the first and second configuration portions C1 and C2 to a direction parallel to the desired polarization direction PD. For example, the polarization direction PD can be adjusted by changing the arrangement of the first and second configuration portions C1 and C2 between the state of FIG. 42A and the state of FIG. 42B. That is, the polarization direction to be controlled can be adjusted by changing the direction of the strain to be applied to the active layer 103.

### Method 1 of Controlling Magnitude of Applied Stress by Stress Application Structure

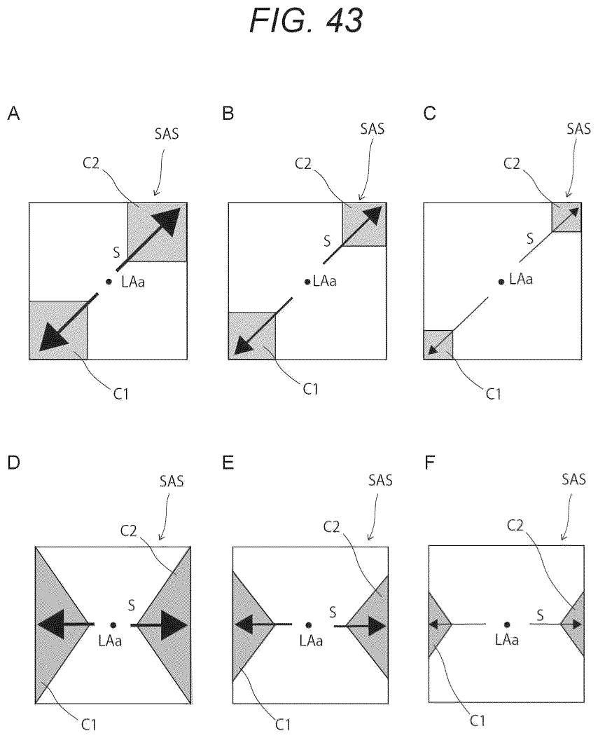

FIGS. 43A to 43F are views for describing a method of controlling magnitude of the applied stress (tensile stress) by the stress application structure that causes a tensile strain in the active layer 103. As illustrated in FIGS. 43A to 43C, as the first and second configuration portions C1 and C2 of the stress application structure SAS are closer to the center LAa of the light emitting region LA, an applied stress S becomes larger, and the polarization controllability is improved. Similarly, as illustrated in FIGS. 43D to 43F, as the first and second configuration portions C1 and C2 of the stress application structure SAS are closer to the center LAa of the light emitting region LA, the applied stress S becomes larger, and the polarization controllability is improved. A polarization ratio (polarization extinction ratio) of polarized light to be controlled can be adjusted by changing an absolute value of the strain in the active layer 103.

### Method 2 of Controlling Magnitude of Applied Stress by Stress Application Structure

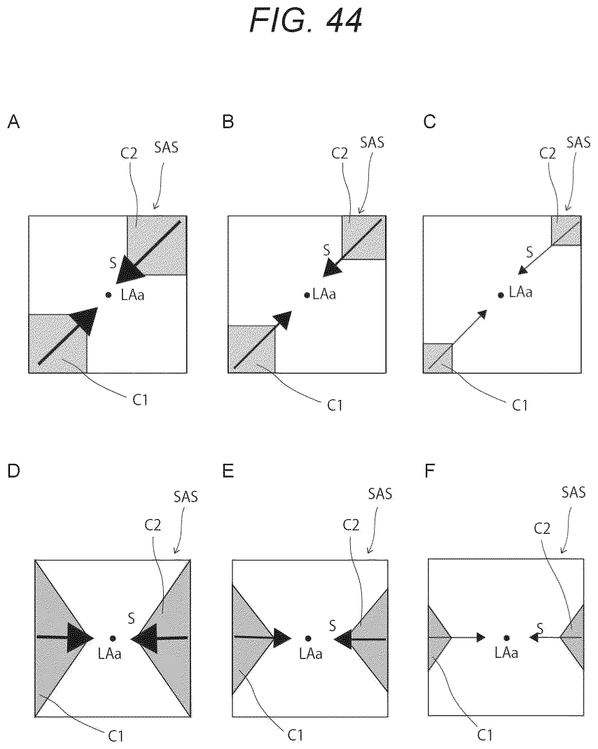

FIGS. 44A to 44F are views for describing a method of controlling magnitude of the applied stress (compressive stress) by a stress application structure that causes a compressive strain in the active layer 103. As illustrated in FIGS. 44A to 44C, as the first and second configuration portions C1 and C2 of the stress application structure SAS are closer to the center LAa of the light emitting region LA, the applied stress S becomes larger. Similarly, as illustrated in FIGS. 44D to 44F, as the first and second configuration portions C1 and C2 of the stress application structure SAS are closer to the center LAa of the light emitting region LA, the applied stress S becomes larger, and the polarization controllability is improved. The polarization ratio (polarization extinction ratio) of the polarized light to be controlled can be adjusted by changing the absolute value of the strain in the active layer 103.

### 16. Surface Emitting Laser According to Example 16 of Embodiment of Present Technology

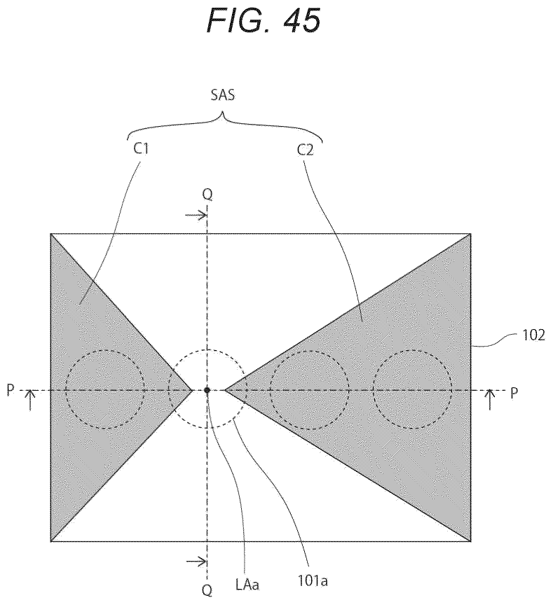

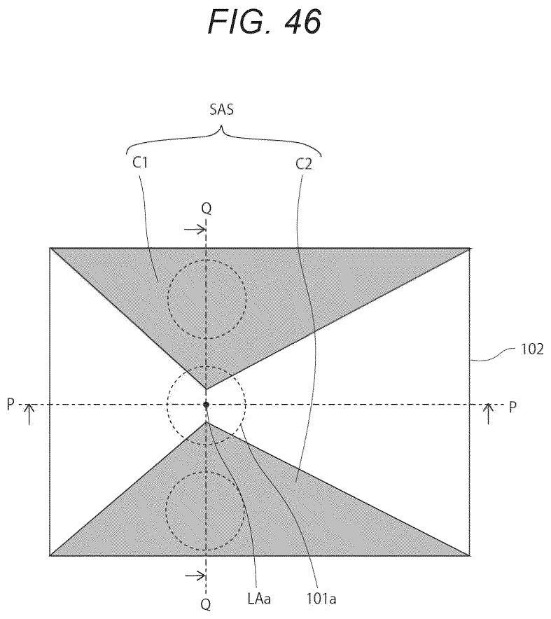

FIG. 45 is a view illustrating a planar configuration example 1 of the first reflecting mirror 102 of the surface emitting laser according to Example 16 of the embodiment of the present technology. FIG. 46 is a view illustrating a planar configuration example 2 of the first reflecting mirror 102 of the surface emitting laser according to Example 16 of the embodiment of the present technology.

The surface emitting laser according to Example 16 has a similar configuration to the surface emitting laser 10-8 according to Example 8 except that a dummy lens-shaped portion 101a that does not contribute to laser oscillation is provided on the back surface of the substrate 101 in addition to the lens-shaped portion 101a of the resonator.

In the planar configuration example 1 illustrated in FIG. 45 and the planar configuration example 2 illustrated in FIG. 46, the lens-shaped portion 101a of the resonator and a plurality of the dummy lens-shaped portions 101a are disposed in the stress application direction that is the arrangement direction of the first and second configuration portions C1 and C2 of the stress application structure SAS (the P-P line direction in FIG. 45 and the Q-Q line direction in FIG. 46). Since a stress distribution is generated around each lens-shaped portion 101a, the plurality of lens-shaped portions 101a is disposed in the stress application direction of the stress application structure SAS, so that the stress applied to the active layer 103 in at least one direction can be increased. Furthermore, for example, when the first reflecting mirror 102 is bonded to a CAN package, the stress around each lens-shaped portion 101a increases, so that the stress applied to the active layer 103 in at least one direction can be further increased.

The surface emitting laser according to Example 16 can be manufactured by a similar manufacturing method to the method of manufacturing the surface emitting laser 10-8 according to Example 8 except that the plurality of lens-shaped portions 101a is formed.

According to the surface emitting laser according to Example 16, it is possible to obtain similar effects to those of the surface emitting laser 10-1 according to Example 1, and it is possible to further improve the polarization controllability by combining the applied stress by the stress application structure SAS and the stress by the plurality of lens-shaped portions 101a.

### 17. Surface Emitting Laser According to Example 17 of Embodiment of Present Technology

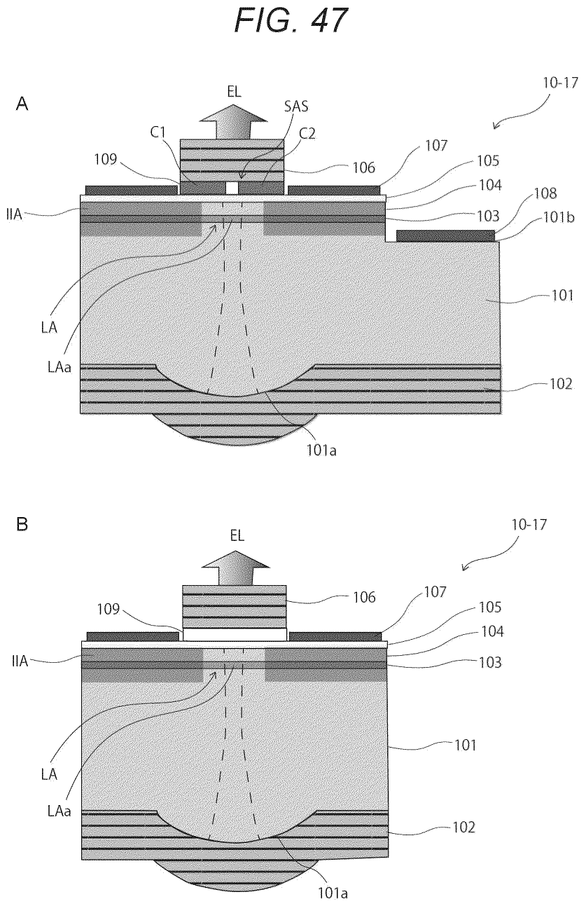

FIG. 47A is a cross-sectional view (part 1) of a surface emitting laser 10-17 according to Example 17 of the embodiment of the present technology. FIG. 47B is a cross-sectional view (part 2) of the surface emitting laser 10-17 according to Example 17 of the embodiment of the present technology.

The surface emitting laser 10-17 has a similar configuration to the surface emitting laser 10-1 according to Example 1 except that a contact layer 109 (intermediate layer) disposed between the second reflecting mirror 106 and the transparent conductive film 105 has the stress application structure SAS.

The contact layer 109 includes a dielectric such as SiN, SiO₂, or SiON, for example. The contact layer 109 plays a role of adjusting a phase of emitted light for phase matching.

The surface emitting laser 10-17 can be manufactured by a similar manufacturing method to the method of manufacturing the surface emitting laser 10-1 according to Example 1 except that the contact layer 109 is patterned on the transparent conductive film 105 and then the contact layer 109 is etched to form the stress application structure SAS.

According to the surface emitting laser 10-17, it is possible to obtain substantially similar effects to those of the surface emitting laser 10-1 according to Example 1.

### 18. Surface Emitting Laser Array According to Example 18 of Embodiment of Present Technology

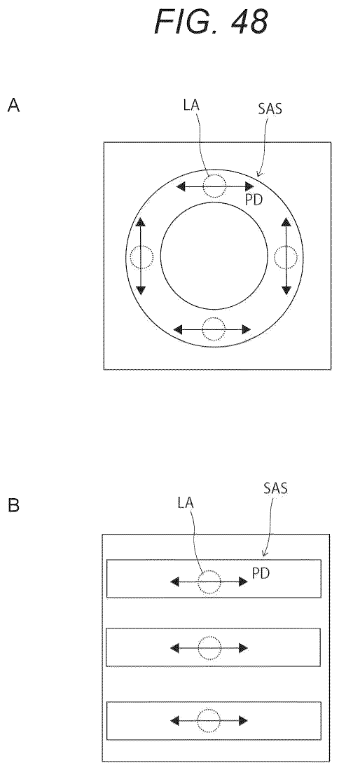

FIG. 48A is a view illustrating a planar configuration example of a surface emitting laser array according to Example 18 of the embodiment of the present technology.

In the surface emitting laser array according to Example 18, in the surface emitting laser array in which a plurality of the surface emitting lasers of any one of Examples 1 to 17 is disposed in a two-dimensional array, the stress application structure SAS formed of an annular void in plan view provided in a material layer or the annular material layer itself in plan view is provided over the light emitting regions LA of a plurality of (for example, four) surface emitting lasers disposed at four vertexes of, for example, a square. In this case, the polarization direction PD can be controlled for each light emitting region LA.

### 19. Surface Emitting Laser Array According to Example 19 of Embodiment of Present Technology

FIG. 48B is a view illustrating a planar configuration example of a surface emitting laser array according to Example 19 of the embodiment of the present technology.

In the surface emitting laser array according to Example 19, in the surface emitting laser array in which a plurality of the surface emitting lasers of any one of Examples 1 to 17 is disposed in a one-dimensional array, the stress application structure SAS formed of a rectangular void in plan view provided in the material layer or the rectangular material layer itself in plan view is provided for each light emitting region LA of each surface emitting laser. In this case, the polarization direction PD can be controlled for each light emitting region LA.

### 20. Surface Emitting Laser According to Example 20 of Embodiment of Present Technology

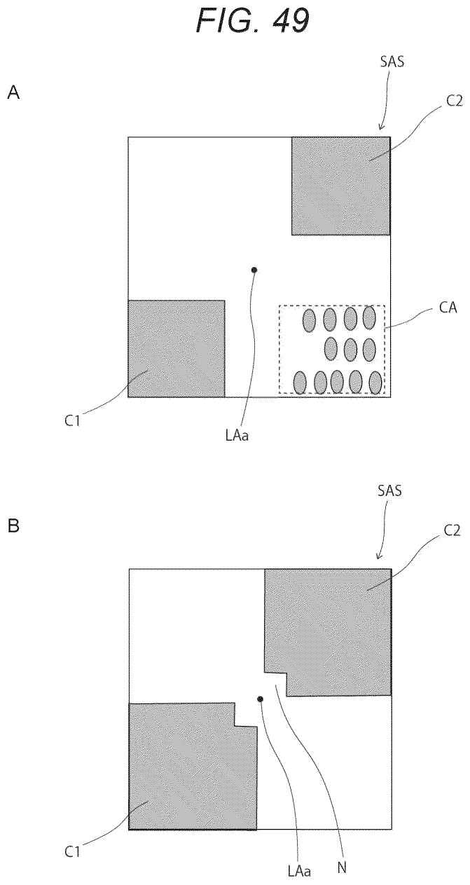

FIG. 49A is a view illustrating a planar configuration example of the surface emitting laser according to Example 20 of the embodiment of the present technology.

In the surface emitting laser according to Example 20, in any of the surface emitting lasers of Example 1 to 17, for example, in a case where a chip has a chip address CA as illustrated in FIG. 49A, the first and second configuration portions C1 and C2 are disposed so that the applied stress due to the stress application structure SAS does not concentrate on the chip address CA. For example, the first and second configuration portions C1 and C2 are disposed in a diagonal direction of the chip such that the stress application direction does not intersect with the chip address CA.

### 21. Surface Emitting Laser According to Example 21 of Embodiment of Present Technology

FIG. 49B is a view illustrating a planar configuration example of the surface emitting laser according to Example 21 of the embodiment of the present technology.

In the surface emitting laser according to Example 21, in any of the surface emitting lasers of Examples 1 to 17, for example, in a case where it is desired to avoid etching of a region corresponding to the vicinity of the center LAa of the light emitting region LA, the stress application structure SAS is patterned such that a notch N is formed in a portion close to the center LAa of the light emitting region LA of the first and second configuration portions C1 and C2 of the stress application structure SAS in advance.

### Influence of Stress Application Structure on Warpage of Substrate

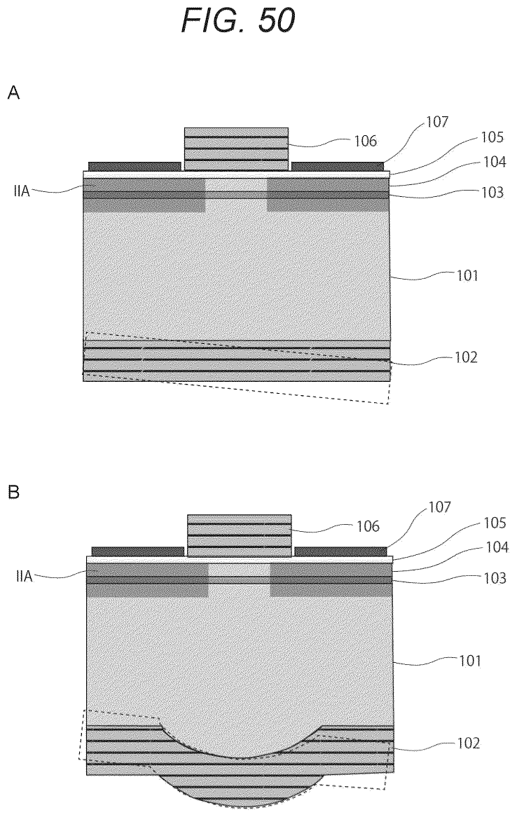

FIG. 50A is a cross-sectional view of a surface emitting laser using a plane mirror as the first reflecting mirror 102. FIG. 50B is a cross-sectional view of a surface emitting laser using a concave mirror as the first reflecting mirror 102. In the surface emitting laser of FIG. 50A, the plane mirror is inclined according to warpage of the substrate 101, and a reflection direction changes by the inclination, so that the influence on the laser characteristics is significant. In the surface emitting laser of FIG. 50B, even if the concave mirror is inclined according to the warpage of the substrate 101, the reflection direction hardly changes with respect to the inclination, so that the influence on the laser characteristics is very small and robustness is high. That is, since the first reflecting mirror 102 has the concave mirror structure, performance of the resonator can be stabilized against the warpage of the substrate 101 caused by the stress application.

### Variation 1 of Stress Application Structure

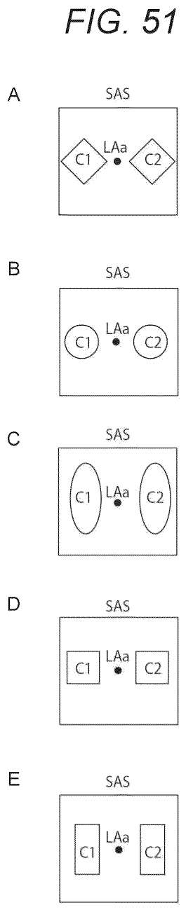

FIGS. 51A to 51E are views illustrating Variation 1 of the stress application structure. In FIGS. 51A to 51E, the first and second configuration portions C1 and C2 of the stress application structure SAS are disposed in at least one material layer among a plurality of material layers constituting a surface emitting laser chip so as to be separated in the longitudinal direction or the lateral direction of the chip in plan view and to be substantially point-symmetric with respect to the center LAa of the light emitting region LA. The first and second configuration portions C1 and C2 may be the material layer itself or may be voids around the material layer.

In the example of FIG. 51A, the first and second configuration portions C1 and C2 each has a square shape in plan view, and are disposed such that respective diagonals of the square shapes are located on a same straight line.

In the example of FIG. 51B, the first and second configuration portions C1 and C2 each has a circular shape in plan view, and are disposed such that respective centers of the circular shapes are located on a same straight line.

In the example of FIG. 51C, the first and second configuration portions C1 and C2 each has an elliptical shape in plan view, and are disposed such that respective major axis directions of the elliptical shapes and the arrangement direction are orthogonal to each other. Note that respective minor axis directions of the elliptical shapes and the arrangement direction may be orthogonal to each other.

In the example of FIG. 51D, the first and second configuration portions C1 and C2 each has a square shape in plan view, and are disposed such that one sides of the square shapes face each other.

In the example of FIG. 51E, the first and second configuration portions C1 and C2 each has a rectangular shape in plan view, and are disposed such that long sides of the rectangular shapes face each other. Note that short sides may be disposed to face each other.

### Variation 2 of Stress Application Structure

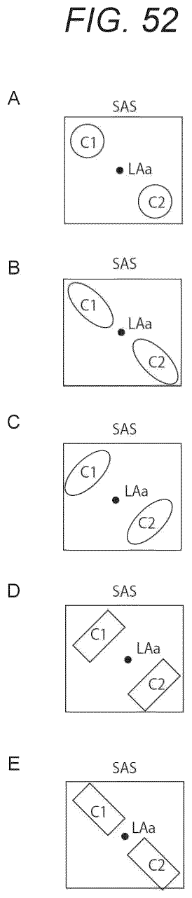

FIGS. 52A to 52E are views illustrating Variation 2 of the stress application structure. In FIGS. 52A to 52E, the first and second configuration portions C1 and C2 of the stress application structure SAS are disposed in at least one material layer among a plurality of material layers constituting a surface emitting laser chip so as to be separated in the diagonal direction of the chip in plan view and to be substantially point symmetric with respect to the center LAa of the light emitting region LA. The first and second configuration portions C1 and C2 may be the material layer itself or may be voids around the material layer.

In the example of FIG. 52A, the first and second configuration portions C1 and C2 each has a circular shape in plan view, and are disposed such that respective centers of the circular shapes are located on a same straight line.

In the example of FIG. 52B, the first and second configuration portions C1 and C2 each has an elliptical shape in plan view, and are disposed such that respective major axes of the elliptical shapes are located on a same straight line.

In the example of FIG. 52C, the first and second configuration portions C1 and C2 each has an elliptical shape in plan view, and are disposed such that respective minor axes of the elliptical shapes are located on a same straight line.

In the example of FIG. 52D, the first and second configuration portions C1 and C2 each has a rectangular shape in plan view, and are disposed such that long sides of the rectangular shapes face each other.

In the example of FIG. 52E, the first and second configuration portions C1 and C2 each has a rectangular shape in plan view, and are disposed such that short sides of the rectangular shapes face each other.

### Variation 3 of Stress Application Structure

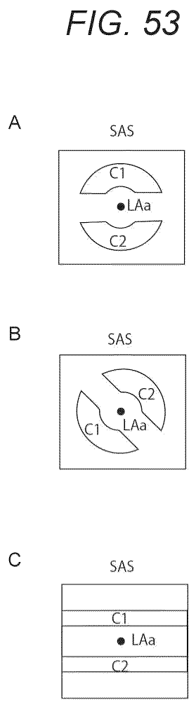

FIGS. 53A to 53E are views illustrating Variation 3 of the stress application structure. In FIGS. 53A to 53E, the first and second configuration portions C1 and C2 of the stress application structure SAS are disposed in at least one material layer among a plurality of material layers constituting a surface emitting laser chip so as to be substantially point-symmetric with respect to the center LAa of the light emitting region LA in plan view. The first and second configuration portions C1 and C2 may be the material layer itself or may be voids around the material layer.

In the example of FIG. 53A, the first and second configuration portions C1 and C2 each has an arc shape in plan view, and are disposed such that inner diameter sides face each other in a longitudinal direction or a lateral direction of the chip.

In the example of FIG. 53B, the first and second configuration portions C1 and C2 each has an arc shape in plan view, and are disposed such that the inner diameter sides face each other in a diagonal direction of the chip.

In the example of FIG. 53C, the first and second configuration portions C1 and C2 each has a rectangular shape in plan view, and are disposed such that long sides face each other in the longitudinal direction or the lateral direction of the chip. Note that short sides may be disposed to face each other.

### 22. Modification of Present Technology

The present technology is not limited to each of the above examples, and various modifications can be made.

For example, in the surface emitting laser 10-7 according to Example 7, the first reflecting mirror 102 may also have the stress application structure SAS. That is, the first reflecting mirror 102 itself may have a shape having anisotropy. Also in this case, it is preferable to adjust the directions of the stress application directions of the plurality of stress application structures SAS in plan view according to whether the applied stresses of the plurality of stress application structures SAS are positive or negative.

For example, the stress application structure SAS may be provided in a plurality of layers having different functions. For example, the stress application structure SAS may be provided in the entire region in the thickness direction (stacking direction) of the first structure. For example, the stress application structure SAS may be provided in the entire region in the thickness direction (stacking direction) of the second structure.

For example, the plurality of stress application structures may include the first and second stress application structures on the same side in the stacking direction of the active layer 103, and the first and second stress application structures may have the same positive and negative applied stresses of the structures themselves. In this case, the angle formed by the stress application directions of the first and second stress application structures is preferably less than 45° in plan view, more preferably less than 30°, still more preferably less than 15°, and still more preferably less than 5°. Furthermore, in this case, the overlap ratio between the first and second stress application structures in plan view is preferably more than 50%, more preferably more than 65%, still more preferably more than 80%, and still more preferably more than 95%. Furthermore, in this case, for example, the first and second stress application structures may be provided in the first reflecting mirror 102 and the substrate 101, respectively, or may be provided on any two of the cladding layer 104, the transparent conductive film 105, the contact layer 109, and the second reflecting mirror 106.

For example, the plurality of stress application structures may include the first and second stress application structures on the same side in the stacking direction of the active layer 103, and the first and second stress application structures may have different positive and negative applied stresses of the structures themselves. In this case, the angle formed by the stress application directions of the first and second stress application structures is preferably more than 45° in plan view, more preferably more than 60°, still more preferably more than 75°, and still more preferably more than 85°. Furthermore, in this case, the overlap ratio between the first and second stress application structures in plan view is preferably less than 50%, more preferably less than 35%, still more preferably less than 20%, and still more preferably less than 5%. Furthermore, in this case, for example, the first and second stress application structures may be provided in the first reflecting mirror 102 and the substrate 101, respectively, or may be provided on any two of the cladding layer 104, the transparent conductive film 105, the contact layer 109, and the second reflecting mirror 106.

For example, even in a case where the chip shape, size, or arrangement of the surface emitting laser is different, it is possible to cope with the difference by forming an appropriate stress application structure.

The stress application structure SAS can be provided in any layer other than the active layer 103 of the surface emitting laser. For example, the stress application structure SAS may be provided in the substrate 101 and/or the cladding layer 104 and/or the transparent conductive film 105 as the intermediate layer. For example, the surface emitting laser according to the present technology may include, for example, an antireflection film, a passivation film, or the like as a layer provided with the stress application structure SAS. Note that “providing the stress application structure SAS in a layer” includes forming first and second configuration portions having shape anisotropy as a whole in the layer and forming the layer itself in a shape having anisotropy.

For example, the cathode electrode 108 may be provided on the back surface (surface opposite to the active layer 103 side) of the substrate 101. In this case, the stress application structure SAS may be provided in the cathode electrode 108.

In the first reflecting mirror 102, a ratio of the film thickness at the position 100 μm away from the center LAa of the light emitting region LA in the in-plane direction to the film thickness at the position of the center LAa of the light emitting region LA may be 0.6 or more, or less than 0.6. As a result, since a step is generated in the first reflecting mirror 102, an additional stress can be generated in a case where the first reflecting mirror 102 side of the surface emitting laser is mounted in, for example, a CAN package, and this stress can also be applied to the active layer 103.

The surface emitting laser according to the present technology preferably includes a group III-V compound semiconductor. Specifically, the present technology can also be applied to an InP-based surface emitting laser, a GaAs surface emitting laser, or the like instead of the GaN-based surface emitting laser described above.

At least one of the first and second reflecting mirror 102 or 106 may be, for example, a semiconductor multilayer film reflecting mirror, a hybrid mirror including a semiconductor multilayer film reflecting mirror and a metal reflecting mirror, a hybrid mirror including a dielectric multilayer film reflecting mirror and a metal reflecting mirror, or the like.

The conductivity types (p-type and n-type) of the configuration layers of the surface emitting laser according to each of the above examples may be interchanged.

Some of the configurations of the surface emitting lasers according to each of the above examples may be combined within a range in which they do not contradict each other.

In each of the above examples, the material, thickness, width, length, shape, size, layout, and the like of each configuration element constituting the surface emitting laser can be appropriately changed within a range functioning as the surface emitting laser.

### 23. Application Example to Electronic Device

The technology according to the present disclosure (the present technology) can be applied to various products (electronic devices). For example, the technology according to the present disclosure may further be realized as a device (for example, a distance measuring device, a shape recognition device, or the like) to be mounted on any type of moving bodies such as automobiles, electric vehicles, hybrid electric vehicles, motorcycles, bicycles, personal mobilities, airplanes, drones, ships, and robots.

The surface emitting laser according to the present technology can also be applied as, for example, a light source or a display itself of a device (for example, a laser printer, a laser copier, a projector, a head-mounted display, a head-up display, or the like) that forms or displays an image by laser light.

The surface emitting laser according to the present technology can also be applied to, for example, an individual authentication device. That is, it is also possible to provide an individual authentication device including a surface emitting laser according to the present technology in which a pattern (emission pattern) formed by emitted light is allocated to an individual, and a processing unit that receives light from the surface emitting laser and performs individual authentication. Specifically, a plurality of surface emitting lasers having different convex surface structures and special structures (emission patterns are different from each other) are prepared, emission patterns of the surface emitting lasers are allocated to individual living bodies, objects, or the like in advance, and a light receiving unit of the processing unit is irradiated with light from the surface emitting lasers, whereby the individual allocated to the surface emitting lasers can be authenticated.

### 24. Example in which Surface Emitting Laser is Applied to Distance Measuring Device

Hereinafter, application examples of the surface emitting laser according to each of the above-described examples and modifications will be described.

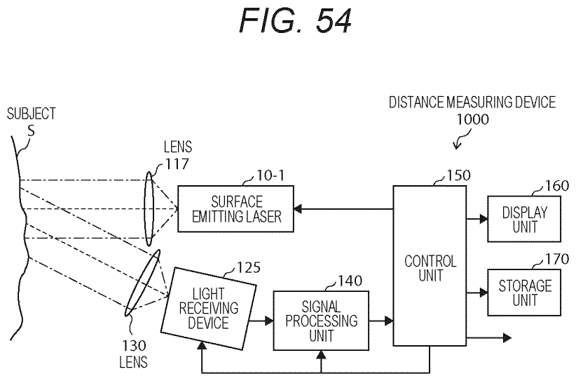

FIG. 54 illustrates an example of a schematic configuration of a distance measuring device 1000 including the surface emitting laser 10-1 as an example of an electronic device according to the present technology. The distance measuring device 1000 measures a distance to a subject S by a time of flight (TOF) method. The distance measuring device 1000 includes the surface emitting laser 10-1 as a light source. The distance measuring device 1000 includes, for example, the surface emitting laser 10-1, a light receiving device 125, lenses 117 and 130, a signal processing unit 140, a control unit 150, a display unit 160, and a storage unit 170.

The surface emitting laser 10-1 is driven by a laser driver (driver). The laser driver has an anode terminal and a cathode terminal connected to an anode electrode and a cathode electrode of the surface emitting laser 10-1, respectively, via a wiring or a conductive bump. The laser driver includes, for example, circuit elements such as a capacitor and a transistor.

The light receiving device 125 detects light reflected by the subject S. The lens 117 is a lens for collimating the light emitted from the surface emitting laser 10-1, and is a collimating lens. The lens 130 is a lens for condensing light reflected by the subject S and guiding the light to the light receiving device 125, and is a condenser lens.

The signal processing unit 140 is a circuit for generating a signal corresponding to a difference between a signal input from the light receiving device 125 and a reference signal input from the control unit 150. The control unit 150 includes, for example, a time to digital converter (TDC). The reference signal may be a signal input from the control unit 150, or may be an output signal of a detecting unit that directly detects the output of the surface emitting laser 10-1. The control unit 150 is, for example, a processor that controls the surface emitting laser 10-1, the light receiving device 125, the signal processing unit 140, the display unit 160, and the storage unit 170. The control unit 150 is a circuit that measures a distance to the subject S on the basis of a signal generated by the signal processing unit 140. The control unit 150 generates a video signal for displaying information about the distance to the subject S, and outputs the video signal to the display unit 160. The display unit 160 displays the information regarding the distance to the subject S on the basis of the video signal input from the control unit 150. The control unit 150 stores information about the distance to the subject S in the storage unit 170.

In the present application example, any one of the surface emitting lasers according to Examples 2 to 17, 20, and 21 described above and the surface emitting laser arrays according to Examples 18 and 19 can be applied to the distance measuring device 1000, instead of the surface emitting laser 10-1. Note that, in a case where the surface emitting laser array is applied to the distance measuring device 1000, a driver capable of individually driving a plurality of surface emitting lasers can also be used.

### 25. Example of Mounting Distance Measuring Device on Moving Body

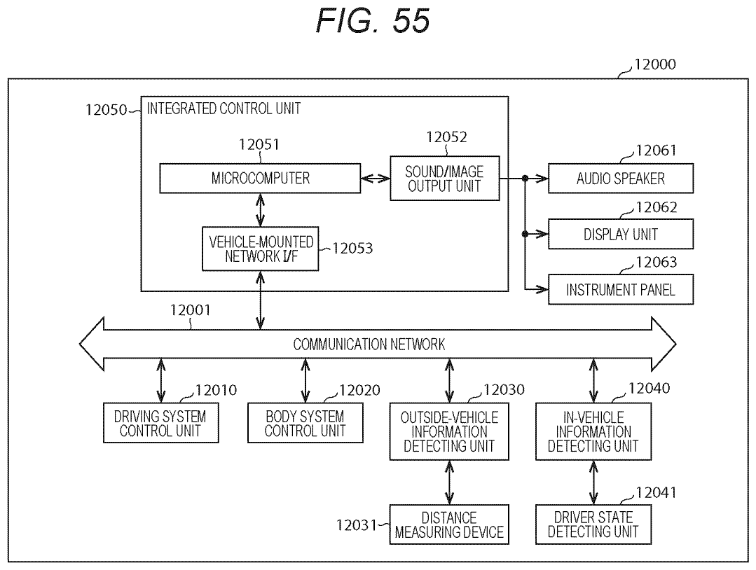

FIG. 55 is a block diagram illustrating a schematic configuration example of a vehicle control system that is an example of a moving body control system to which the technology according to the present disclosure may be applied.

The vehicle control system 12000 includes a plurality of electronic control units connected to each other via a communication network 12001. In the example illustrated in FIG. 55, the vehicle control system 12000 is provided with a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output unit 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, a distance measuring device 12031 is connected to the outside-vehicle information detecting unit 12030. The distance measuring device 12031 includes the distance measuring device 1000 described above. The outside-vehicle information detecting unit 12030 causes the distance measuring device 12031 to measure a distance to an object (subject S) outside the vehicle, and acquires distance data acquired by the measurement. The outside-vehicle information detecting unit 12030 may perform object detection processing of a person, a car, an obstacle, a sign, or the like on the basis of the acquired distance data.

The in-vehicle information detecting unit 12040 detects information about the inside of the vehicle. The in-vehicle information detecting unit 12040 is, for example, connected with a driver state detecting unit 12041 that detects the state of a driver. The driver state detecting unit 12041 includes, for example, a camera that images the driver. On the basis of detection information input from the driver state detecting unit 12041, the in-vehicle information detecting unit 12040 may calculate a degree of fatigue of the driver or a degree of concentration of the driver, or may determine whether or not the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

Furthermore, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output unit 12052 transmits an output signal of at least one of a sound and an image to an output device capable of visually or auditorily notifying information to an occupant of the vehicle or the outside of the vehicle. In the example in FIG. 55, as the output device, an audio speaker 12061, a display unit 12062, and an instrument panel 12063 are illustrated. The display unit 12062 may include, for example, at least one of an on-board display and a head-up display.

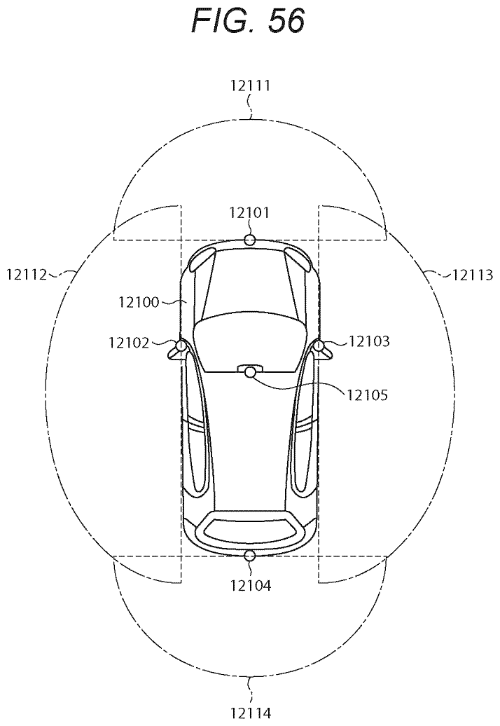

FIG. 56 is a view illustrating an example of an installation position of the distance measuring device 12031.

In FIG. 56, vehicle 12100 includes distance measuring devices 12101, 12102, 12103, 12104, and 12105 as the distance measuring device 12031.

For example, the distance measuring devices 12101, 12102, 12103, 12104, and 12105 are provided at positions such as a front nose, sideview mirrors, a rear bumper, a back door, an upper portion of a windshield in a vehicle interior, and the like of the vehicle 12100. The distance measuring device 12101 provided at the front nose and the distance measuring device 12105 provided at the upper portion of the windshield in the vehicle interior mainly acquire data of the front side of the vehicle 12100. The distance measuring devices 12102 and 12103 provided at the sideview mirrors mainly acquire data of the sides of the vehicle 12100. The distance measuring device 12104 provided at the rear bumper or the back door mainly acquires data of the rear side of the vehicle 12100. The data of the front side acquired by the distance measuring devices 12101 and 12105 is mainly used to detect a preceding vehicle, a pedestrian, an obstacle, a traffic light, a traffic sign, or the like.

Note that FIG. 56 illustrates an example of detection ranges of the distance measuring devices 12101 to 12104. A detection range 12111 indicates a detection range of the distance measuring device 12101 provided at the front nose, detection ranges 12112 and 12113 indicate detection ranges of the distance measuring devices 12102 and 12103 provided at the sideview mirrors, respectively, and a detection range 12114 indicates a detection range of the distance measuring device 12104 provided at the rear bumper or the back door.

For example, the microcomputer 12051 obtains a distance to each three-dimensional object within the detection ranges 12111 to 12114 and a temporal change in the distance (relative speed with respect to the vehicle 12100) on the basis of the distance data obtained from the distance measuring devices 12101 to 12104, thereby extracting particularly a nearest three-dimensional object present on a traveling path of the vehicle 12100, which travels in substantially the same direction as the vehicle 12100 at a predetermined speed (for example, equal to or more than 0 km/h), as a preceding vehicle. Moreover, the microcomputer 12051 can set a following distance to be maintained in front of a preceding vehicle in advance, and perform automatic brake control (including follow-up stop control), automatic acceleration control (including follow-up start control), or the like. It is thus possible to perform cooperative control intended for automated driving that makes the vehicle travel automatedly without depending on the operation of the driver or the like.

For example, the microcomputer 12051 can classify three-dimensional object data regarding three-dimensional objects into two-wheeled vehicles, standard-sized vehicles, large-sized vehicles, pedestrians, and other three-dimensional objects such as utility poles, extract the three-dimensional object data, and use the three-dimensional object data for automatic avoidance of obstacles, on the basis of the distance data obtained from the distance measuring devices 12101 to 12104. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is higher than or equal to a set value and there is thus a possibility of collision, the microcomputer 12051 can outputs a warning to the driver via the audio speaker 12061 or the display unit 12062 and perform forced deceleration or avoidance steering via the driving system control unit 12010 to perform driving assistance for collision avoidance.

An example of the moving body control system to which the technology according to the present disclosure can be applied has been described above. The technology according to the present disclosure may be applied to the distance measuring device 12031 among the configurations described above.

Furthermore, the present technology may also adopt the following configurations.
(1) A surface emitting laser including:
a resonator including
a first structure and a second structure stacked on each other and
an active layer disposed between the first and second structures, in which
the first structure and/or the second structure is provided with a stress application structure that applies a stress that distorts the active layer in an in-plane direction to the active layer.
(2) The surface emitting laser according to (1), in which the stress application structure has shape anisotropy in the in-plane direction.
(3) The surface emitting laser according to (1) or (2), in which the stress application structure distorts the active layer in at least one direction in a plane.
(4) The surface emitting laser according to any one of (1) to (3), in which the stress application structure has shape anisotropy in directions orthogonal to each other in the in-plane direction.
(5) The surface emitting laser according to any one of (1) to (4), in which the resonator is provided with a current confinement region that sets a light emitting region of the active layer, and the stress application structure includes a first configuration portion provided on one side of a center of the light emitting region in plan view and a second configuration portion provided on another side.
(6) The surface emitting laser according to (5), in which the first and second configuration portions are substantially point-symmetric with respect to the center of the light emitting region in plan view.
(7) The surface emitting laser according to any one of (1) to (6), in which the stress application structure is provided in at least a part of the first structure and/or the second structure in a stacking direction.
(8) The surface emitting laser according to any one of (1) to (7), in which the stress application structure has a single layer structure or a multilayer structure.
(9) The surface emitting laser according to any one of (1) to (8), in which a plurality of the stress application structures is disposed at different positions in at least a stacking direction.
(10) The surface emitting laser according to (9), in which the plurality of stress application structures includes first and second stress application structures on a same side in the stacking direction of the active layer, the first and second stress application structures each has an applied stress having a same positive or negative sign, and an angle formed by stress application directions of the first and second stress application structures in plan view is less than 45°.
(11) The surface emitting laser according to (9) or (10), in which the plurality of stress application structures includes first and second stress application structures on a same side in the stacking direction of the active layer, the first and second stress application Structures each has an applied stresses having a different positive or negative sign, and an angle formed by stress application directions of the first and second stress application structures in plan view exceeds 45°.
(12)

The surface emitting laser according to any one of (9) to (11), in which
the plurality of stress application structures includes first and second stress application structures on different sides in the stacking direction of the active layer,
the first and second stress application structures each has an applied stress having a same positive or negative sign, and
an angle formed by stress application directions of the first and second stress application structures in plan view exceeds 45°.
(13)

The surface emitting laser according to any one of (9) to (12), in which
the plurality of stress application structures includes first and second stress application structures on different sides in the stacking direction of the active layer,
the first and second stress application structures each has an applied stress having a different positive or negative sign, and
an angle formed by stress application directions of the first and second stress application structures in plan view is less than 45°.
(14) The surface emitting laser according to any one of (1) to (13), in which the first structure includes a first reflecting mirror, the second structure includes a second reflecting mirror, and the first reflecting mirror and/or the second reflecting mirror has the stress application structure.
(15) The surface emitting laser according to any one of (1) to (14), in which the second structure includes a reflecting mirror, and at least one intermediate layer disposed between the reflecting mirror and the active layer, and the intermediate layer has the Stress application structure.
(16) The surface emitting laser according to (15), in which the second structure includes a transparent conductive film disposed between the reflecting mirror and the active layer, and the intermediate layer is disposed between the reflecting mirror and the transparent conductive film.
(17) The surface emitting laser according to any one of (1) to (16), in which the first structure includes a reflecting mirror, and at least one intermediate layer disposed between the reflecting mirror and the active layer, and the intermediate layer has the stress application structure.
(18) The surface emitting laser according to (17), in which the intermediate layer includes a substrate.
(19) The surface emitting laser according to any one of (1) to (18), in which the second structure is provided with an electrode, and the electrode has the stress application structure.
(20) The surface emitting laser according to any one of (1) to (19), in which the first structure is provided with an electrode, and the electrode has the stress application structure.
(21) The surface emitting laser according to any one of (1) to (20), in which a resonator length of the resonator is 50 μm or less.
(22) The surface emitting laser according to any one of (1) to (21), in which the first structure includes a reflecting mirror including a concave mirror.
(23) The surface emitting laser according to any one of (1) to (22), in which a thickness of the surface emitting laser is 100 μm or less.

### REFERENCE SIGNS LIST

10-1 to 10-17 Surface emitting laser
101 Substrate (intermediate layer)
102 First reflecting mirror
103 Active layer
104 Cladding layer (intermediate layer)
105 Transparent conductive film
106 Second reflecting mirror
107 Anode electrode (electrode)
108 Cathode electrode (electrode)
109 Contact layer (intermediate layer)
SAS Stress application structure
C1 First configuration portion
C2 Second configuration portion
LA Light emitting region
LAa Center of light emitting region
IIA Ion implantation region (current confinement region)

1. A surface emitting laser comprising:
a resonator including
a first structure and a second structure stacked on each other and
an active layer disposed between the first and second structures, wherein
the first structure and/or the second structure is provided with a stress application structure that applies a stress that distorts the active layer in an in-plane direction to the active layer.

2. The surface emitting laser according to claim 1, wherein the stress application structure has shape anisotropy in the in-plane direction.

3. The surface emitting laser according to claim 1, wherein the stress application structure distorts the active layer in at least one direction in a plane.

4. The surface emitting laser according to claim 1, wherein the stress application structure has shape anisotropy in directions orthogonal to each other in the in-plane direction.

5. The surface emitting laser according to claim 1, wherein
the resonator is provided with a current confinement region that sets a light emitting region of the active layer, and
the stress application structure includes a first configuration portion provided on one side of a center of the light emitting region in plan view and a second configuration portion provided on another side.

6. The surface emitting laser according to claim 5, wherein the first and second configuration portions are substantially point-symmetric with respect to the center of the light emitting region in plan view.

7. The surface emitting laser according to claim 1, wherein the stress application structure is provided in at least a part of the first structure and/or the second structure in a stacking direction.

8. The surface emitting laser according to claim 1, wherein the stress application structure has a single layer structure or a multilayer structure.

9. The surface emitting laser according to claim 1, wherein a plurality of the stress application structures is disposed at different positions in at least a stacking direction.

10. The surface emitting laser according to claim 9, wherein
the plurality of stress application structures includes first and second stress application structures on a same side in the stacking direction of the active layer,
the first and second stress application structures each has an applied stress having a same positive or negative sign, and
an angle formed by stress application directions of the first and second stress application structures in plan view is less than 45°.

11. The surface emitting laser according to claim 9, wherein
the plurality of stress application structures includes first and second stress application structures on a same side in the stacking direction of the active layer,
the first and second stress application structures each has an applied stresses having a different positive or negative sign, and
an angle formed by stress application directions of the first and second stress application structures in plan view exceeds 45°.

12. The surface emitting laser according to claim 9, wherein
the plurality of stress application structures includes first and second stress application structures on different sides in the stacking direction of the active layer,
the first and second stress application structures each has an applied stress having a same positive or negative sign, and
an angle formed by stress application directions of the first and second stress application structures in plan view exceeds 45°.

13. The surface emitting laser according to claim 9, wherein
the plurality of stress application structures includes first and second stress application structures on different sides in the stacking direction of the active layer,
the first and second stress application structures each has an applied stress having a different positive or negative sign, and
an angle formed by stress application directions of the first and second stress application structures in plan view is less than 45°.

14. The surface emitting laser according to claim 1, wherein
the first structure includes a first reflecting mirror,
the second structure includes a second reflecting mirror, and
the first reflecting mirror and/or the second reflecting mirror has the stress application structure.

15. The surface emitting laser according to claim 1, wherein
the second structure includes
a reflecting mirror, and
at least one intermediate layer disposed between the reflecting mirror and the active layer, and
the intermediate layer has the stress application structure.

16. The surface emitting laser according to claim 15, wherein
the second structure includes a transparent conductive film disposed between the reflecting mirror and the active layer, and
the intermediate layer is disposed between the reflecting mirror and the transparent conductive film.

17. The surface emitting laser according to claim 1, wherein
the first structure includes
a reflecting mirror, and
at least one intermediate layer disposed between the reflecting mirror and the active layer, and
the intermediate layer has the stress application structure.

18. The surface emitting laser according to claim 17, wherein the intermediate layer includes a substrate.

19. The surface emitting laser according to claim 1, wherein
the second structure is provided with an electrode, and
the electrode has the stress application structure.

20. The surface emitting laser according to claim 1, wherein
the first structure is provided with an electrode, and
the electrode has the stress application structure.
